(19) United States
(12) Patent Application Publication
(10) Pub. No.: US 2018/0138453 A1
(43) Pub. Date: May 17, 2018

(54) HIGH CONTRAST LIGHT EMITTING DEVICE

(71) Applicant: Cambridge Display Technology Limited, Cambridgeshire (GB)

(72) Inventors: Jeremy BURROUGHES, Cambridge (GB); Nicholas DARTNELL, Cambridgeshire (GB); Arne FLEISSNER, Regensburg (DE)

(73) Assignee: Cambridge Display Technology Limited, Cambridgeshire (GB)

(21) Appl. No.: 15/571,913

(22) PCT Filed: Apr. 28, 2016
(86) PCT No.: PCT/EP2016/059562

§ 371 Date: Nov. 6, 2017

(30) Foreign Application Priority Data
May 6, 2015 (GB) 1507726.6

(51) Int. Cl. H01L 51/52; H01L 51/50

(52) U.S. Cl. CPC H01L 51/5259; H01L 51/5032; H01L 51/5284; H01L 51/5246; H01L 51/5221

(57) ABSTRACT

An organic light emitting device having a layered structure comprising: a getter layer (6); an adhesive layer (5); a non-transparent cathode layer (4); a light-emitting layer (3); and a transparent anode layer (2); wherein the getter layer or adhesive layer include light absorbing materials to improve contrast in use.

### FIELD OF THE INVENTION

The present invention relates to a layered structure for an organic electronic device and to an organic electronic device comprising the layered structure. The invention also relates to a method for making the layered structure and the organic electronic device.

### BACKGROUND

Organic electronic devices provide many potential advantages including inexpensive, low temperature, large scale fabrication on a variety of substrates including glass and plastic. Examples of such devices are organic light emitting diodes (OLEDs) and light emitting electrochemical cells (LECs).

Organic light emitting diode (OLED) displays, for example, provide additional advantages as compared with other display technologies—in particular they are bright, colourful, fast-switching and provide a wide viewing angle. OLED devices (which here include organometallic devices and devices including one or more phosphors) may be fabricated using either polymers or small molecules in a range of colours and in multi-coloured displays depending upon the materials used. For general background information reference may be made, for example, to WO90/13148, WO95/06400, WO99/48160 and U.S. Pat. No. 4,539,570, as well as to “Organic Light Emitting Materials and Devices” edited by Zhigang Li and Hong Meng, CRC Press (2007), ISBN 10: 1-57444-574X, which describes a number of materials and devices, both small molecule and polymer.

In its most basic form an OLED comprises a light emitting layer which is positioned in between an anode and a cathode. In operation holes are injected through the anode into the light emitting layer and electrons are injected into the light emitting layer through the cathode. The holes and electrons combine in the light emitting layer to form an exciton which then undergoes radiative decay to provide light.

In its basic form a light emitting electrochemical cell (LEC) comprises a light emitting layer which is positioned in between an anode and a cathode. The light emitting layer also comprises an electrolyte and a salt(s). Light is generated when holes and electrons, injected from the anode and cathode respectively, combine in the light emitting layer. For general background information on LECs, reference may be made to U.S. Pat. No. 5,682,043 and WO2011/032010.

In LECs, when a voltage is first applied across the light emitting layer the salts present therein dissociate and migrate towards the electrode having the opposite charge to the respective dissociated ion. Over time the charges accumulate at each electrode and act to dope the polymer effectively then bending the energy bands between the electrode and the light emitting polymer enabling injection of charge carriers from the electrodes onto the polymer backbone. An advantage of an LEC compared to an OLED is therefore that it is not necessary to match the energy level of the cathode with the light emitting layer by, for example, including an air sensitive low work function metal in the cathode. As a result, fabrication methods for the manufacture of LECs can potentially be carried out in air.

A problem with existing LECs presently on the market is that their operational lifetime is mainly limited by an increase in the drive voltage over time, i.e. the voltage required to drive a constant current through the device increases over time. In practice, the drive voltage will increase until it reaches the voltage compliance limit of the device, at which point the driver can no longer maintain a constant current. As a result, the current density in the device is reduced and there is a consequent sharp decline in luminance from the device.

Another problem with LECs presently available is a slow turn-on speed either in initial operation or after a period where the device has not been in use, due to the need to dissociate and/or move the ions from the salt through the light emitting layer. As a result, the turn-on time of an LEC device can be in tens of seconds to minutes, making such devices unsuitable for use for some applications. Hence there remains a need for LECs with longer operational lifetimes and improved turn-on speeds.

A further problem with LECs presently available is an insufficient contrast for some applications. In order to enhance the contrast, external neutral density filters have been suggested. Said filters enhance the contrast but at the same time reduce the light output and require the device to be driven harder overall, which would in-turn reduce operational lifetime.

### BRIEF DESCRIPTION OF THE DRAWINGS

FIG. 1 is a schematic drawing of a preferred embodiment of the invention.

FIG. 2 is an example of lifetest traces for a device having an evaporated Ag cathode, showing the increase in voltage required to achieve a constant current throughout the device over time. The rightmost vertical dashed line indicates the point at which, for this example, the maximum drive voltage of the driver circuitry is reached (34 V, after 200 hours) at which point the driver cannot maintain the constant current, resulting in a reduced current density and consequently a sharp decline in luminance output of the device.

FIG. 3 is a voltage vs. time plot for devices with evaporated cathodes comprising silver and carbon as the cathode material.

FIG. 4 is a voltage vs. time plot for devices with evaporated carbon and silver cathodes and for devices having screen printed silver and carbon cathodes.

FIG. 5 is a voltage vs. time plot for devices with a screen printed carbon cathode and a screen printed silver cathode.

FIG. 6 is a luminance vs. time plot for devices with a carbon cathode and a silver cathode.

FIG. 7 illustrates an LEC device stack in accordance with the present invention.

FIG. 8 is illustrates another LEC device stack in accordance with the present invention.

FIG. 9 shows the results of a contrast comparison of the LECs of Example 5.

### SUMMARY OF INVENTION

The present invention provides an organic light emitting device comprising:
a getter layer;
an optional non-reflective layer;
an optional adhesive layer;
a non-transparent cathode layer;
a light-emitting layer;
an optional organic electron transport layer; and
a transparent anode layer;

wherein at least one of conditions (i) to (iii) is fulfilled:
i) the getter layer comprises pigments,
ii) a non-reflective layer is provided between the getter layer and the cathode layer, and
iii) the adhesive layer comprises pigments.

The present invention further provides an organic electronic device comprising the above layered structure.

The present invention also provides a method of producing the above layered structure comprising the steps of:
providing a light emitting layer on a substrate;
optionally depositing an organic electron transport layer on said light emitting layer;
depositing a non-transparent cathode on said light emitting layer or, when present, said organic electron transport layer;
optionally depositing an adhesive layer which comprises pigments on said cathode layer;
optionally depositing a non-reflective layer on said cathode layer or, if present, said optional adhesive layer; and
depositing a getter layer on said cathode layer or, if present, either said optional adhesive layer or said optional non-reflective layer.

The present invention furthermore provides a method of producing the above organic electronic device comprising:
providing an anode layer on a substrate;
depositing a light emitting layer on said anode;
drying said light emitting layer;
optionally depositing an organic electron transport layer on said light emitting layer;
depositing a non-transparent cathode layer on said light emitting layer or, when present, said organic electron transport layer;
optionally depositing an adhesive layer which comprises pigments on said cathode layer;
optionally depositing a non-reflective layer on said cathode layer or, if present, said optional adhesive layer; and
depositing a getter layer on said cathode layer or, if present, either said optional adhesive layer or said optional non-reflective layer.

Preferred embodiments are set forth in the subclaims.

### Definitions

As used herein the term “electrode” refers to an anode or a cathode.

As used herein the term “non-transparent carbon” refers to carbon which is not transparent to visible light, i.e. light having a wavelength of 380 to 740 nm.

As used herein the term “carbon black” refers to paracrystalline carbon.

As used herein the term “ink” refers to a composition comprising conductive particles, a resin and a solvent.

As used herein the term “resin” is used to refer to a polymer which forms a continuous matrix in which the conductive particles can be dispersed.

As used herein the term “screen printing” refers to a process wherein a squeegee or blade is used to apply force or pass ink through a mesh which has areas of the mesh blocked in a patternwise fashion so that the ink is transferred through the mesh to an underlying substrate forms a negative of the blocked pattern on the mesh.

As used herein the term “vapour deposition” refers to thermal evaporation in a vacuum.

As used herein the term “polymer” refers to a compound comprising repeating units. Polymers usually have a polydispersity of greater than 1.

As used herein the term “light emitting polymer” refers to a polymer that emits light.

As used herein the term “charge transporting polymer” refers to a polymer that can transport holes or electrons.

As used herein the term “polar” refers to a separation of charge within the structure of a molecule. “Polar groups” are those groups wherein there is a covalent bond between two atoms wherein the electrons forming the bond are unequally distributed. The term encompasses electrical dipole moments where the distribution of charge in the bond is only slightly uneven creating a slightly positive end and a slightly negative end. The term also encompasses zwitterions and ionic groups where the charge separation is complete.

As used herein the term “salt” refers to an ionic substance comprising a cation and a counteranion.

As used herein the term “cross linkable group” refers to a group comprising an unsaturated bond or a precursor capable of in situ formation of an unsaturated bond that can undergo a bond-forming reaction.

As used herein the term “alkyl” refers to saturated, straight chained, branched or cyclic groups. Alkyl groups may be substituted or unsubstituted.

As used herein the term “haloalkyl” refers to saturated, straight chained, branched or cyclic groups in which one or more hydrogen atoms are replaced by a halogen atom, e.g. F or Cl, especially F.

As used herein, the term “cycloalkyl” refers to a saturated or partially saturated mono- or bicyclic alkyl ring system containing 3 to 10 carbon atoms. Cycloalkyl groups may be substituted or unsubstituted.

As used herein, the terms “heterocycloalkyl” and “heterocyclic” refers to a cycloalkyl group in which one or more ring carbon atoms are replaced by at least one hetero atom such as —O—, —N— or —S—. Heterocycloalkyl groups may be substituted or unsubstituted.

As used herein the term “alkenyl” refers to a straight chained, branched or cyclic group comprising a double bond. Alkenyl groups may be substituted or unsubstituted.

As used herein the term “alkynyl” refers to straight chained, branched or cyclic groups comprising a triple bond. Alkynyl groups may be substituted or unsubstituted.

Optional substituents that may be present on alkyl, cycloalkyl, heterocycloalkyl, alkenyl and alkynyl groups as well as the alkyl moiety of an arylalkyl group include C₁₋₁₆ alkyl or C₁₋₁₆ cycloalkyl wherein one or more non-adjacent C atoms may be replaced with O, S, N, C═O and —COO—, substituted or unsubstituted C₅₋₁₄ aryl, substituted or unsubstituted C₅₋₁₄ heteroaryl, C₁₋₁₆ alkoxy, C₁₋₁₆ alkylthio, halo, e.g. fluorine and chlorine, cyano and arylalkyl.

As used herein, the term “aryl” refers to a group comprising at least one aromatic ring. The term aryl encompasses heteroaryl as well as fused ring systems wherein one or more aromatic ring is fused to a cycloalkyl ring. Aryl groups may be substituted or unsubstituted.

As used herein, the term “heteroaryl” refers to a group comprising at least one aromatic ring in which one or more ring carbon atoms are replaced by at least one hetero atom such as —O—, —N— or —S—.

Optional substituents that may be present on aryl or heteroaryl groups as well as the aryl moiety of arylalkyl groups include halide, cyano, C₁₋₁₆ alkyl, C₁₋₁₆ fluoroalkyl, C₁₋₁₆ alkoxy, C₁₋₁₆ fluoroalkoxy, C₅₋₁₄ aryl and C₅₋₁₄ heteroaryl.

As used herein, the term “arylalkyl” refers to an alkyl group as hereinbefore defined that is substituted with an aryl group as hereinbefore defined.

As used herein, the term “heteroarylalkyl” refers to an alkyl group as hereinbefore defined that is substituted with a heteroaryl group as hereinbefore defined.

As used herein the term “halogen” encompasses atoms selected from the group consisting of F, Cl, Br and I.

As used herein the term “alkoxy” refers to O-alkyl groups, wherein alkyl is as defined above.

As used herein the term “aryloxy” refers to O-aryl groups, wherein aryl is as defined above.

As used herein the term “arylalkoxy” refers to O-arylalkyl groups, wherein arylalkyl is as defined above.

As used herein the term “alkylthio” refers to S-alkyl groups, wherein alkyl is as defined above.

As used herein the term “arylthio” refers to S-aryl groups, wherein aryl is as defined above.

As used herein the term “arylalkylthio” refers to S-arylalkyl groups, wherein arylalkyl are as defined above.

As used herein the term “dry nitrogen atmosphere” refers to an atmosphere of nitrogen having less than about 10 ppm O₂ and water content.

### DESCRIPTION OF THE INVENTION

The present invention provides a layered structure for an organic electronic device comprising:
a getter layer;
an optional non-reflective layer;
an optional adhesive layer;
a non-transparent cathode layer;
a light-emitting layer;
an optional organic electron transport layer; and
a transparent anode layer;

wherein at least one of conditions (i) to (iii) are fulfilled:
i) the getter layer comprises pigments,
ii) a non-reflective layer is provided between the getter layer and the cathode layer, and
iii) the adhesive layer comprises pigments.

Advantageously, with the present invention contrast enhancement is achieved without the need of an external filter, such as an external neutral density filter. The contrast enhancement is achieved by either the layered structure comprising i) a getter layer which comprises pigments, in particular dark pigments; and/or ii) by the layered structure additionally comprising a non-reflective or contrast layer in between the getter layer and the cathode layer, wherein said non-reflective layer preferably comprises dark pigments; and/or iii) by the layered structure comprising an adhesive layer in between the cathode layer and the getter layer wherein the adhesive layer comprises pigments, preferably dark pigments. Of course, said different features may be combined to enhance the contrast even further. In return, the high contrast allows for devices comprising the layered structure of the present invention to be operated at a lower luminescence level as compared to a device requiring external filters, resulting in more stable devices and longer lifetimes of the device. Even without external filters, the devices comprising the layered structure of the present invention advantageously allow for operation at lower drive conditions.

Furthermore, the clarity of pixels is improved, and unwanted features, such as cathode tack lines, can be masked, leading to an improved overall visual appearance.

In a preferred embodiment, the layered structure comprises a non-transparent cathode layer which comprises a carbon material or a metal. The cathode layer is preferably a non-reflective layer.

Suitable carbon materials include isotropic graphite, anisotropic graphite, agranular carbon, non-graphitizable carbon, amorphous carbon, carbon black, carbon fibre, and mixtures thereof. Preferably the non-transparent carbon is carbon black. Preferably the non-transparent carbon material does not comprise graphene. Typically the non-transparent carbon has a sheet resistance of around 50-1500 Ω/sq for a thickness of 1 micrometer, for example 125-1,250 Ω/sq for a thickness of 1 micrometer as measured on 5 mm polyester film. Preferably the non-transparent carbon has an abrasion resistance as measured by pencil hardness (ASTM D3363-74) of around 1-5, preferably around 1-3, more preferably around 2. The cathode may also be made of metal materials. Suitable metal materials for the cathode include Ag, Al, Au, Cd, Cr, Cu, Ga, In, Li, Ni, Pb, Pt, Pt black, Sn, Ti and Zn. Preferred are Ag, Al, Au, Ni Pt Black and Pt, with Ag, Al, Au, Pt and Pt black being more preferred.

Preferably, if the cathode comprises a metal, the cathode is a non-reflective cathode or of reduced reflectivity. For example, the metal of the cathode can be applied as an uneven surface, drastically reducing the reflexibility thereof. Examples of non-reflective materials include metals such as Pt black. Of course, the preferred non-reflective materials may further be applied such that the surface becomes uneven, thereby even further of reducing reflectivity.

It is also preferred that the cathode appears dark, i.e. non-reflective, in use to provide a visual match to the dark getter layer.

Preferably the layer of carbon material or metal is substantially continuous. More preferably the layer of carbon material is continuous. Preferably a substantially continuous layer of the carbon material or metal is present, and substantially all of the substantially continuous layer of the carbon material or metal is in contact with the light emitting layer or, when present, the organic electron transport layer on at least one surface of the carbon material or metal. Preferably no intermediate layers are present between the cathode and the light emitting layer or, when present, the organic electron transport layer. Preferably the carbon material or metal is directly in contact with the light emitting layer or the organic electron transport layer. The cathode comprising non-transparent carbon material or metal results in the electrical performance of organic electronic devices comprising it being significantly improved compared to devices comprising conventional cathodes.

The layered structure of the present invention optionally further comprises a bus bar. Preferably the bus bar is present on a surface of the cathode opposite to the light emitting layer or, where present, the organic electron transport layer. Any suitable bus bar may be used, e.g. a silver track. Bus bars are especially preferred in case the non-transparent cathode layer comprises a low conductivity material, such as low conducting carbon material.

In the layered structure of the present invention, the cathodes are preferably not transparent to visible light, i.e. light having a wavelength of 380 to 740 nm.

In some preferred layered structures of the present invention, the cathodes preferably further comprise one or more resins. A resin may be present when screen printing is used to deposit the cathode. The resin is preferably a polymer. The polymer may be a thermoplastic polymer or a thermosetting polymer. Optionally the resin is cross linked. Preferably the resin comprises an alkyl cellulose, a poly(meth)acrylic, a poly(meth)acrylate, a styrene, an acrylamide, a vinyl ether, a polyvinyl alcohol or mixtures thereof. Still more preferably the resin comprises an alkyl cellulose, a poly(meth)acrylic, a poly(meth)acrylate or mixtures thereof. Suitable resins for use in the methods and inks of the present invention are commercially available from, for example, Sigma Aldrich. The purpose of the resin is to provide a continuous matrix for the carbon particles during printing so that when the printed ink is subsequently heated, the carbon particles come in contact with each other or coalesce to form a continuous carbon track. Preferably the cathode comprises 10-99 wt % carbon and 1-90 wt % resin. More preferably the cathode comprises 25-99 wt % carbon and 1-75 wt % resin, still more preferably 50-99 wt % carbon and 1-50 wt % resin.

In other further layered structures of the invention, the cathode comprises substantially no resin. In such layered structures, the cathode is preferably formed by vapour deposition.

In a more preferred embodiment, the electroluminescent device of the present invention is an “all-printed device. “All-printed” refers to all layers of the device being formed using a printing technique, such as include screen printing, gravure printing, dispense printing, nozzle printing, flexographic printing, roll to roll printing, dip coating, slot die coating, doctor blade coating or ink-jet printing. If the device is an all-printed device, no methods such as the afore-mentioned vapour deposition are employed.

Cathodes of the layered structures of the present invention may also comprise a solvent. Solvent may be present when, for example, the cathode is deposited by printing. The purpose of the solvent is to dissolve the resin for printing. The dissolution of the resin ensures that a homogenous resin/conductive carbon particle mixture is formed which in turn leads to a more even distribution of the conductive carbon particles during and after printing. The printed carbon layer will then be dried or cured to remove the solvent. Preferably the cathodes comprise only residual solvent, preferably less than 1 wt % solvent, more preferably less than 0.5 wt % solvent, still more preferably less than 0.1 wt % solvent. More preferably the cathodes comprise only trace amounts of solvent. Preferably the cathodes are substantially free of solvents.

In preferred embodiments of the invention, the layered structure comprises a cathode which does not comprise a low work function metal. Preferably the cathodes contain substantially no Ag, Al, Na, or salts, alloys or mixtures thereof. Preferably the cathodes contain substantially no NaF. Low work function metals include Ca, Li, Cs, Ba and Mg.

The cathodes of the layered structures of the present invention may be deposited by any suitable method. The cathode may, for example, be deposited by vapour deposition. Suitable methods include thermal evaporation, e-beam evaporation and sputtering. In such embodiments, the cathode contains substantially no resin and substantially no solvent. Alternatively, the cathode may be deposited by depositing an ink. Preferably the cathode is deposited by printing. Suitable printing methods include screen printing, gravure printing, dispense printing, nozzle printing, flexographic printing, roll to roll printing, dip coating, slot die coating, doctor blade coating or ink-jet printing. Screen printing is particularly preferred. Printing, and in particular screen printing, is a highly advantageous process as it enables large area patterning on flexible substrates at relatively low cost.

The layered structure of the present invention comprises a getter layer. In order to improve the contrast of the organic device comprising the layered structure, the getter layer may comprise pigments, preferably dark pigments. Suitable pigments include any pigment which results in a dark, preferably dark grey or black layer. Suitable pigments include carbon materials such as isotropic graphite, anisotropic graphite, agranular carbon, non-graphitizable carbon, amorphous carbon, carbon black, carbon fibre, and mixtures thereof. Also metals may be used as long as the addition results in a dark color of the layer, such as Pt black and the like. Commercial products are known in the art, such as the PAGE® film product line from SAES.

The layered structure of the present invention may optionally comprise a non-reflective layer. The non-reflective layer, or contrast layer, if present, is placed in between the getter layer and the cathode layer. In a preferred embodiment, the non-reflective layer comprises a carbon material or a metal. More preferred is that the non-reflective layer comprises a carbon material or a metal which is identical to the carbon material or metal of the cathode layer. Due to the presence of the non-reflective layer, the contrast can be further enhanced. Particularly preferred is that the color of the non-reflective layer matches the color of the cathode for best contrast enhancement, for example by both layers comprising the same carbon material or metal. In case the non-reflective layer and the cathode layer both comprise electrically conductive materials, such as a metal, preferably the same metal, said layers need to be separated in order to avoid short circuits. Such separation can preferably be achieved by an (intermediate) adhesive layer having insulative properties, thereby effectively preventing any short circuits.

Alternatively, the non-reflective layer can comprise suitable pigments, such as any pigment which results in a dark, preferably dark grey or black layer. Suitable pigments include carbon materials such as isotropic graphite, anisotropic graphite, agranular carbon, non-graphitizable carbon, amorphous carbon, carbon black, carbon fibre, and mixtures thereof. Also metals may be used as long as the addition results in a dark color of the layer, such as Pt black and the like . . .

The non-reflective layer, or contrast layer, if present, is preferably uniformly deposited. This is in contrast to the cathode layer, which is generally deposited pixel wise.

The layered structure of the present invention may optionally comprise an adhesive layer. In a preferred embodiment, the layered structure comprises an adhesive. The adhesive layer, if present, is placed at least in between the getter layer and the cathode layer. In case an additional optional non-reflective layer, or contrast layer, if present, the adhesive is placed in between the getter layer and the non-reflective layer on one side and the cathode layer on the other side. In order to improve the contrast, the adhesive layer, if present, may preferably comprise pigments. Suitable pigments include the pigments mentioned above for the non-reflective layer and the getter layer. If the optional non-reflective layer or contrast layer is present, the adhesive layer, if present, is at least located in between the non-reflective layer and the cathode. In this case, the adhesive preferably comprises a transparent insulator thus allowing for the above described color matching and preventing short circuits between pixels through the non-reflective layer.

The optional adhesive layer is also preferably present for prevention of short circuits, especially in case it is desired to use a getter layer and cathode layer comprising the same materials. Thus, in a more preferred embodiment, the layered structure of the present invention comprises an adhesive layer which comprises a transparent insulator.

Suitable adhesive materials for the adhesive layer in accordance with the present invention are common adhesive materials for electronic devices well known in the art.

In the layered structures of the present invention, the light emitting layer may comprise light emitting material which is polymeric and/or non-polymeric. Any conventional small molecule light emitting material may be used.

In preferred layered structures of the invention, the light emitting layer comprises a light emitting polymer. Preferably the light emitting polymer comprises at least two different monomers and more preferably at least three different monomers. Still more preferably the light emitting polymer layer comprises three, four or five different monomers. Optionally the light emitting layer further comprises a charge transporting polymer. Optionally the light emitting polymer may be a polymer or copolymer comprising monomers comprising substituted or unsubstituted fluorene, phenanthrene or propellane monomers, for example polyfluorene or polyphenanthrene. Polymers or copolymers of this type may further comprise a monomer comprising a phosphorescent group. The phosphorescent group preferably comprises at least one metal, preferably a transition metal. Phosphorescent groups comprising at least one iridium atom are particularly preferred. Alternatively the light emitting polymer may be blended with a compound comprising a phosphorescent group as described above.

The light emitting polymer may comprise a polar group. If the layered structure is present in an LEC, the light emitting polymer preferably comprises a polar group. More preferably the light emitting polymer present in the light emitting layer comprises a repeat unit of formula (Xa) or (Xb):

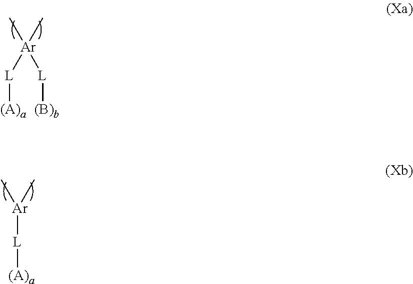

wherein Ar is a C₅₋₂₀ substituted or unsubstituted aryl or heteroaryl group;
L is a bond or a linker group;
A is a polar group;
B is a A, hydrogen, substituted or unsubstituted C₁₋₁₆ alkoxy, substituted or unsubstituted C₅₋₁₄ aryl, substituted or unsubstituted arylalkyl, substituted or unsubstituted C₅₋₁₄ heteroaryl, substituted or unsubstituted heteroarylalkyl and substituted or unsubstituted C₁₋₁₆ alkyl wherein one or more non-adjacent C atoms may be replaced with —O—, —NR—, —NH—, —S—, —COO—, —NHCO—, —NHSO₂—, —NHCOO-groups wherein R is C₁₋₈ alkyl; and
each of a and b are independently an integer selected from 1 to 5.

When either of a or b is greater than 1, there are more than 1 A and B groups respectively attached to the linker, e.g. when a is 2, there are 2 A groups attached to the linker. When multiple A and/or B groups are present, they may be attached to the linker at different atoms.

Preferred light emitting polymers comprise a repeat unit of formula X shown below:

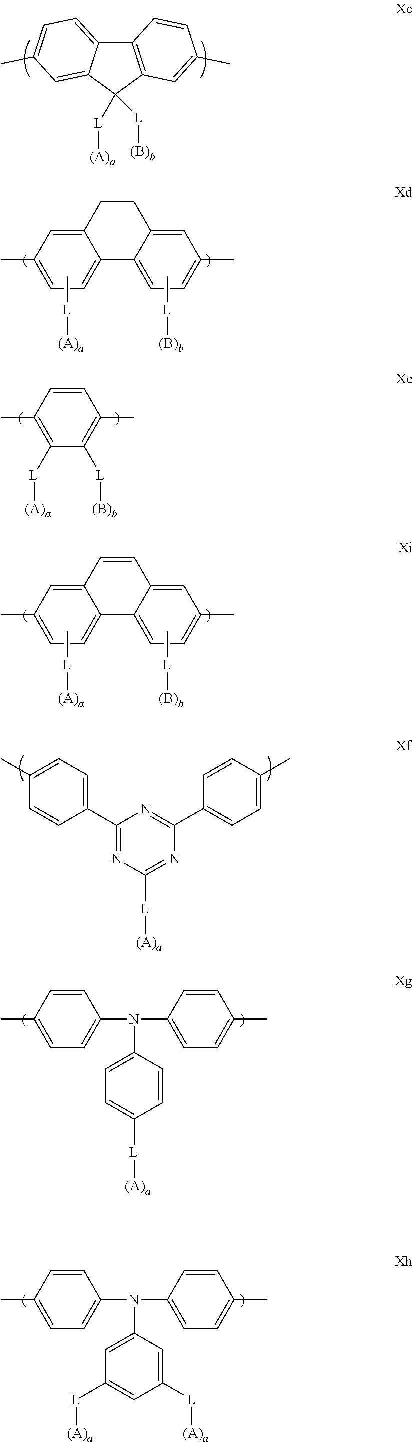

wherein L, A, B, a and b are as defined above in relation to formula Xa and Xb.

Particularly preferably the light emitting polymer comprises repeat units of formula (Xc):

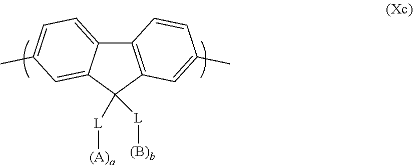

wherein L, A, B, a and b are as defined above in relation to formula Xa and Xb.

In preferred light emitting polymers, (B)b is (A)a, i.e. the repeat unit comprises identical polar groups per unit. In further preferred light emitting polymers a is 1 or 2.

In further preferred light emitting polymers, L is a linker group selected from substituted or unsubstituted C₅₋₁₄ aryl, substituted or unsubstituted C_{5 -14} heteroaryl and substituted or unsubstituted C₁₋₁₆ alkyl wherein one or more non-adjacent C atoms may be replaced with —O—, —NR—, —NH—, —S—, —COO—, —NHCO—, —NHSO₂—, —NHCOO-groups wherein R is C₁₋₅ alkyl. More preferably L is a linker group selected from substituted or unsubstituted C₅₋₁₄ aryl and substituted or unsubstituted C₁₋₁₆ alkyl wherein one or more non-adjacent C atoms may be replaced with —O—, —NR—, —NH—, —S—, —COO—, —NHCO—, —NHSO₂—, —NHCOO-groups wherein R is C₁₋₅ alkyl. In some light emitting polymers, L is a C₅₋₁₄ aryl, especially a C₅ or C₆ aryl, e.g. phenyl. In other light emitting polymers, L is a C₁₋₁₆ alkyl, more preferably a C₁₋₆ alkyl and yet more preferably a C₁₋₄ alkyl.

Particularly preferably the light emitting polymer comprises a repeat unit of formula (Xci) or (Xcii):

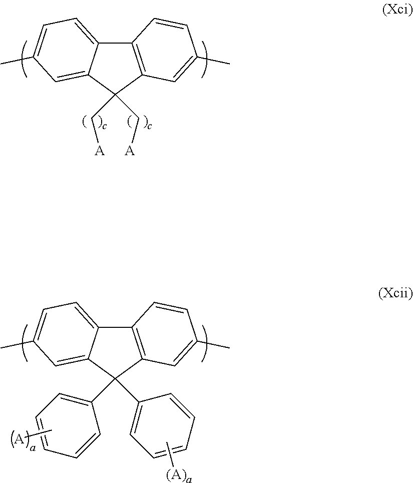

wherein
n is an integer between 1 and 16,
A is a polar group; and
a is an integer from 1 to 5.

Preferably n is an integer between 1 to 6 and yet more preferably an integer between 1 and 4, e.g. 2. Preferably a is 1 or 2. In formula (Xcii) when one A group is present (i.e. a is 1) it is preferably present in the 4 position. In formula (Xcii) when two A groups are present (i.e. a is 2), they are preferably present at the 3 and 4 positions. More preferably the light emitting polymer comprises a repeat unit of formula (Xcii).

In preferred light emitting polymers of the invention, the polar group comprises at least one moiety selected from —NHCO—, —NHSO₂—, —COO—, —COO—, —NHCOO, —O—, —NR—, —NH—, —NO—, —S—, —CF₂— and —CCl₂— wherein R is C₁₋₈ alkyl. Preferably the polar group comprises at least one —O— moiety, and more preferably a plurality of —O— moeities.

Particularly preferred polar groups present in the light emitting polymer of the invention are those of formula:

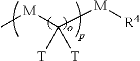

wherein
M is O, NR, NH, S or CQ wherein R is C₁₋₈ alkyl;
Q is Br, Cl, F, I or H;
T is Br, Cl, F, I or H;
o is an integer from 1 to 4;
p is an integer from 1 to 16; and
R⁴ is H or C₁₋₆ alkyl.

In preferred groups, M is O, NR or NH, particularly O.

In further preferred groups, T is Cl, F or H, particularly H.

In further preferred groups, o is 2 or 3, particularly 2.

In further preferred groups, p is 1 to 12. In some groups p is more preferably 3 to 10, and still more preferably 4 to 8. In other groups p is more preferably 2 to 6 and still more preferably 2 or 3.

In further preferred groups, R⁴ is H, —CH₃ or —CH₂CH₃.

Yet more preferred polar groups present in the light emitting polymer of the invention are those of formula:

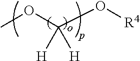

wherein
o is an integer from 1 to 4;
p is an integer from 1 to 16; and
R⁴ is H or C₁₋₆ alkyl.

In preferred groups, o is 2 or 3, particularly 2.

In further preferred groups, p is 1 to 12. In some groups p is more preferably 3 to 10, and still more preferably 4 to 8. In other groups p is more preferably 2 to 6 and still more preferably 2 or 3.

In further preferred groups, R⁴ is H, —CH₃ or —CH₂CH₃.

Especially preferably the polar group present in the light emitting polymer of the invention comprises at least one —(CH₂CH₂O)— unit.

Particularly preferred light emitting polymers present in the light emitting layer of the present invention comprises a repeat unit of formula (Xcf) or (Xcg):

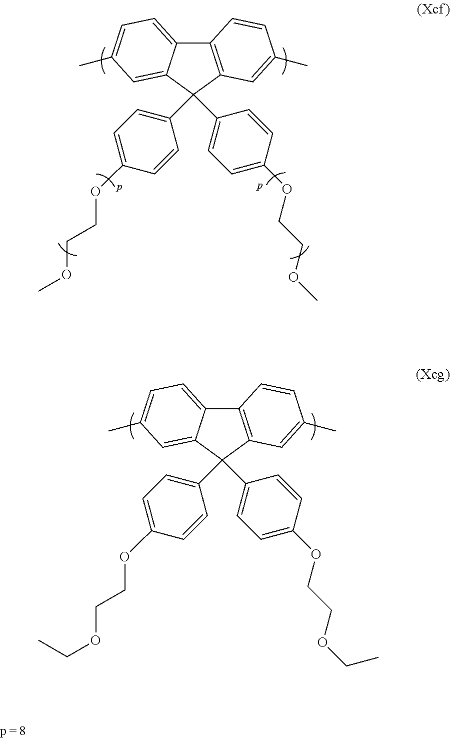

Repeat units of formula (X) may be incorporated into light emitting polymers using appropriate monomers and methods conventional in the art. The skilled man can determine suitable monomers.

The light emitting polymer present in the light emitting layer of the present invention optionally comprises further repeat units. Some preferred light emitting polymers comprise a repeat unit of formula (A) which is an substituted or unsubstituted, 2,7-linked fluorene and more preferably a repeat unit of formula (A) as shown below:

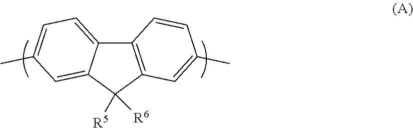

wherein R⁵ and R⁶ are independently selected from hydrogen, unsubstituted or substituted C₁₋₁₆ alkyl, wherein one or more non-adjacent C atoms may be replaced with O, S, N, CO and —COO—, unsubstituted or substituted C₁₋₁₆ alkoxy, unsubstituted or substituted C₅₋₁₄ aryl, unsubstituted or substituted arylalkyl, unsubstituted or substituted C₅₋₁₄ heteroaryl and unsubstituted or substituted heteroarylalkyl. Optional substituents are preferably selected from the group consisting of C₁₋₁₆ alkyl or C₁₋₁₆ cycloalkyl wherein one or more non-adjacent C atoms may be replaced with O, S, N, O═O and —COO—, unsubstituted or substituted C₅₋₁₄ aryl, unsubstituted or substituted C₅₋₁₄ heteroaryl, C₁₋₁₆ alkoxy, C₁₋₁₆ alkylthio, fluorine, cyano and arylalkyl.

In preferred repeat units of formula (A) R⁵ and R⁶ are the same. In particularly preferred repeat units at least one and more preferably both of R⁵ and R⁶ comprise an unsubstituted or substituted C₁₋₁₆ alkyl or an unsubstituted or substituted C₅₋₁₄ aryl, e.g. a C₆ aryl. Preferred substituents of aryl groups are C₁₋₁₆ alkyl and still more preferably an unsubstituted C₁₋₁₆ alkyl group.

Particularly preferred repeat units of formula (A) are shown below. The repeat unit (Ai) is particularly preferred.

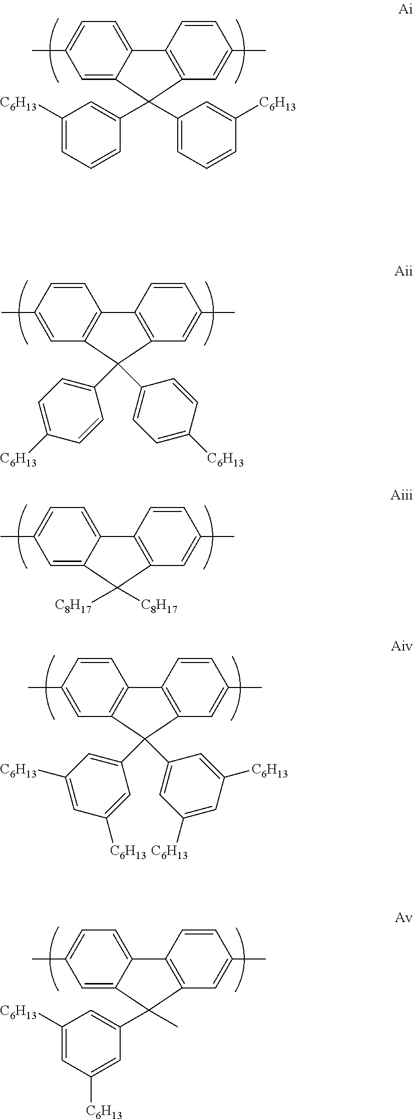

Repeat units of formula (A) may be incorporated into light emitting polymers using monomers as described in WO2002/092723.

Further preferred light emitting polymers present in the light emitting layer comprise repeat units of formula (B):

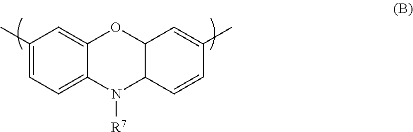

wherein R⁷ is selected from unsubstituted or substituted C₁₋₁₆ alkyl, wherein one or more non-adjacent C atoms may be replaced with O, S, N, CO and —COO—, unsubstituted or substituted C₁₋₁₆ alkenyl, unsubstituted or substituted C₁₋₁₆ alkoxy, unsubstituted or substituted C₅₋₁₄ aryl, unsubstituted or substituted arylalkyl, unsubstituted or substituted C₅₋₁₄ heteroaryl and unsubstituted or substituted heteroarylalkyl. Optional substituents are preferably selected from the group consisting of C₁₋₁₆ alkyl or C₁₋₁₆ cycloalkyl wherein one or more non-adjacent C atoms may be replaced with O, S, N, O═O and —COO—, unsubstituted or substituted C₅₋₁₄ aryl, unsubstituted or substituted C₅₋₁₄ heteroaryl, C₁₋₁₆ alkoxy, C₁₋₁₆ alkylthio, fluorine, cyano and arylalkyl.

In preferred repeat units of formula (B) R⁷ is an unsubstituted or substituted C₅₋₁₄ aryl, e.g. a C₆ aryl. Preferred substituents of aryl groups are C₁₋₁₆ alkyl and still more preferably an unsubstituted C₁₋₁₆ alkyl group such as an unsubstituted C₁₋₆ alkyl group. A particularly preferred repeat unit of formula (B) is shown below as formula (Bi):

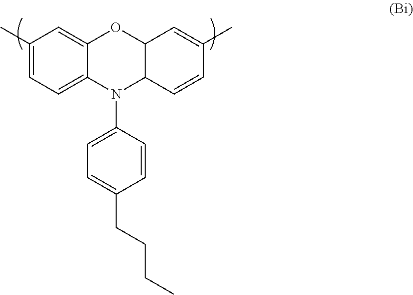

Repeat units of formula (Bi) may be incorporated into light emitting layers using monomers described WO2004/060970.

Preferably the light emitting polymer comprises at least one repeat unit comprising a cross-linkable group. Preferably the at least one repeat unit comprising a cross-linkable group is selected from formulae (Ca) or (Cb):

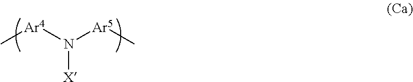

wherein Ar⁴ and Ar⁵ represent C₅₋₁₄ aryl or C₅₋₁₄ heteroaryl and X′ is a cross-linkable group;

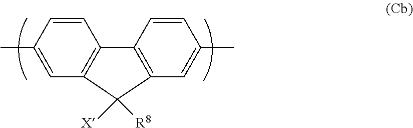

wherein X′ is a cross-linkable group and R⁸ is independently selected from X′, hydrogen, unsubstituted or substituted C₁₋₁₆ alkyl, wherein one or more non-adjacent C atoms may be replaced with O, S, N, CO and —COO—, unsubstituted or substituted C₁₋₁₆ alkenyl, unsubstituted or substituted C₁₋₁₆ alkoxy, optionally substituted C₅₋₁₄ aryl, unsubstituted or substituted arylalkyl, unsubstituted or substituted C₅₋₁₄ heteroaryl and unsubstituted or substituted heteroarylalkyl.

In preferred units of formula (Ca) Ar⁴ and Ar⁵ are the same. In particularly preferred repeat units Ar⁴ and Ar⁵ comprise substituted or unsubstituted C₅₋₁₄ aryl. When present, preferred substituents for Ar⁴ and Ar⁵ include C₁₋₁₆ alkyl and C₁₋₁₆ alkoxy groups. Especially preferred Ar⁴ and Ar⁵ groups are unsubstituted C₆ aryl.

Examples of cross-linkable group X′ in repeat unit (Ca) include moieties containing a double bond, a triple bond, a precursor capable of in situ formation of a double bond, or an unsaturated heterocyclic group. In some preferred repeat units of formula (Ca) the cross-linkable group X′ contains a precursor capable of in situ formation of a double bond. More preferably X′ contains a benzocyclobutanyl group. Especially preferred X′ groups comprise a C₅₋₁₂ aryl group substituted with a benzocyclobutanyl group, particularly preferably C₆ aryl substituted with a benzocyclobutanyl group.

A particularly preferred repeat unit of formula (Ca) is shown below:

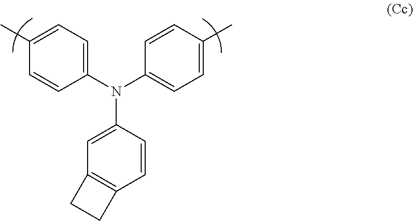

Repeat units of formula (Ca) may be incorporated into light emitting polymers using monomers as described in WO2005/052027.

In preferred repeat units of formula (Cb) X′ is a double bond, a triple bond, a precursor capable of in situ formation of a double bond, or an unsaturated heterocyclic group. In some preferred repeat units of formula (Cb) the cross-linkable group X′ is contains a double bond or is a precursor capable of in situ formation of a double bond. More preferably X′ contains —CH═CH₂ group or a benzocyclobutanyl group. Especially preferred X′ groups comprise a C₁₋₁₆ alkyl group, a C₁₋₁₆ alkylidene group or a C₅₋₁₂ aryl group substituted with a benzocyclobutanyl group, particularly preferably C₁₋₁₆ alkyl grroup substituted with a benzocyclobutanyl group.

In preferred repeat units of formula (Cb) R⁸ is X′. Still more preferably X′ and R⁸ are identical.

Three particularly preferred repeat units of formula (Cb) are shown below. Repeat unit Ci is particularly preferred.

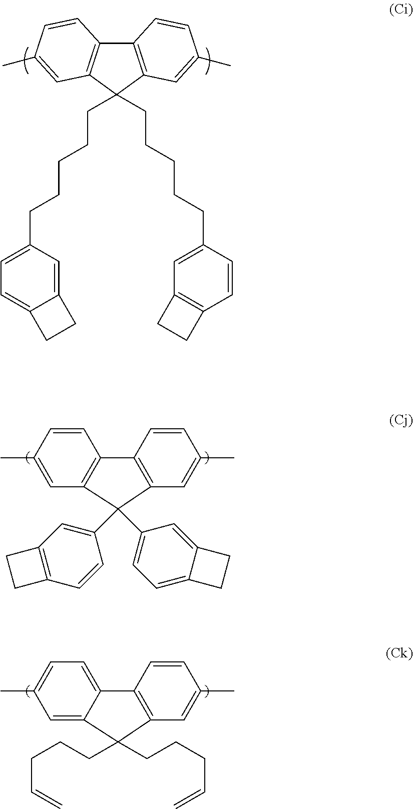

Repeat units of formula (Cb) may be incorporated into light emitting polymers using monomers as described in WO2002/092723.

Preferably the light emitting polymer comprises at least one repeat unit of formula (D):

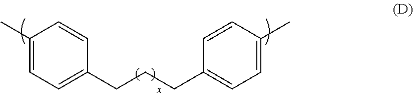

wherein x is selected from an integer between 1 and 6 and more preferably 2, 3, 4 or 5.

A particularly preferred repeat unit of formula (D) is shown below as formula (Di):

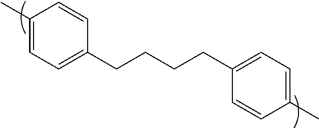

Repeat units of formula (D) may be incorporated into light emitting polymers using monomers as described in WO2013/093400.

Light emitting polymers present in the light emitting layer may optionally contain a light emitting unit. Preferred light emitting units are present as end caps in the polymer. Preferred light emitting units are of formula (E):

ML¹_{q}L²ᵣL³ₛ (E)

wherein M is a metal; each of L¹, L² and L³ is a ligand; q is an integer; r and s are each independently 0 or an integer; and the sum of (a. q)+(b. r)+(c.s) is equal to the number of coordination sites available on M, wherein a is the number of ligating sites on L¹, b is the number of ligating sites on L² and c is the number of ligating sites on L³.

In preferred monomers of formula (E) L¹, L² and L³ are bidentate ligands. In further preferred monomers of formula (E) L¹, L² and L³ are biaryl bidentate ligands, especially preferably biaryl bidentate ligands comprising one or more (e.g. one) heteroatoms. Preferably the heteroatom or heteroatoms are oxygen or nitrogen. In particularly preferred monomers of formula (E) L¹, L² and L³ are biaryl bidentate nitrogen-containing ligands. The preferred metal M is iridium.

Particularly preferred light emitting units of formula (E) are those in which at least one of L¹, L² and L³ are of the following structure:

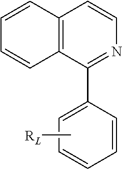

wherein RL is H or Ar′ wherein Ar′ is aryl, especially substituted C₆ aryl.

Preferred light emitting units of formula (E) are as follows:

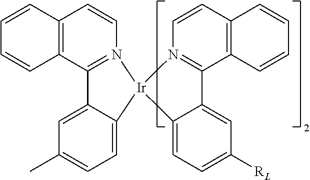

wherein RL is as defined above.

A particularly preferred light emitting of formula (Ei) is shown below:

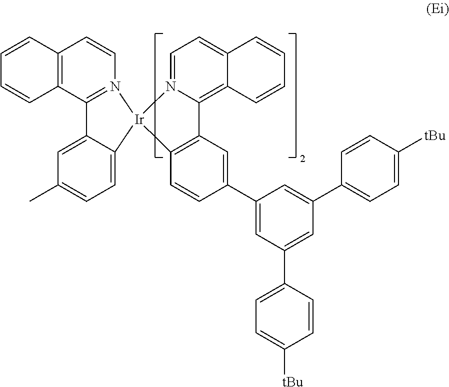

Repeat units of formula (E) may be incorporated into light emitting polymers using appropriate monomers and methods conventional in the art. The skilled man can determine suitable monomers.

In one preferred embodiment the light emitting polymer present in the light emitting layer comprises the repeat units (Xcg) and (Xcf). In another preferred embodiment the light emitting polymer present in the light emitting layer comprises the repeat units (Xg), (Bi), (Ei) and optionally (Xf).

The amount of each of the different repeat units present in the light emitting polymer may vary. Preferably, however, the total wt % of repeat units of formula (X) is 40 to 100%. Preferably the total wt % of repeat units of formula (B) is 10 to 40% wt. Preferably the total wt % of repeat units of formula (E) is 0.01 to 0.1%. Preferably the total wt % of repeat units of formula (A) is 0 to 35%. Preferably the total wt % of repeat units of formula (C) is 0 to 20%. Preferably the total wt % of repeat units of formula (D) is 0 to 20%.

Preferred light emitting polymers are as follows:
LEP1 comprises repeat units (Xcf), (Di), (Ci), (Bi) and (Ei) described above. The ratio of the repeat units is 49.975% wt (Xcf), 5% wt (Di), 15% wt (Ci), 30% wt (Bi) and 0.05% wt (Ei).
LEP2 comprises repeat units (Xcg), (Ai), (Di), (Bi) and (Ei) described above. The ratio of the repeat units is 39.95% wt (Xcg), 25% wt (Ai), 5% wt (Di), 30% wt (Bi) and 0.05% wt (Ei).
LEP3 comprises repeat units (Xcf), (Xcg), (Bi) and (Ei) described above. The ratio of the repeat units is 50% wt (Xcf), 19.95% wt (Xcg), 30% wt (Bi), 0.05% wt (Ei).
LEP4 comprises repeat units (Xcf) and (Xcg) described above. The ratio of the repeat units is 50% wt (Xcf) and 50% wt (Xcg).

Light emitting layers of the present invention may further comprise a salt or a mixture of salts. In light emitting layers of the invention which are present in LECs, the light emitting layer preferably comprises a salt or a mixture of salts. In light emitting layers of the invention which are present in OLEDs, the light emitting layer preferably does not comprise a salt or a mixture of salts. In some devices, e.g. LECs, multiple salts with different ionic sizes help to improve lifetime and efficiency, to achieve faster device turn on while maintaining the longer lifetimes and provide better compatibility with the other components of the light emitting layer.

Representative examples of suitable salts, divided into three groups according to their properties are set out below:

Group I salts for Ionic Mobility—Salts that have smaller anions or cations tend to be more mobile than salts with bulky anions or cations. Examples of salts with small anions include those with anions containing halides (fluorine, bromine, chlorine, and iodine), hexafluorophosphide (PF₆⁻), tetrafluoroborate (BF₄⁻), organoborates, thiocyanate, dicyanamide, alkylsulfates, tosylates, methanesulfonate, trifluoromethanesulfonate, bis(trifluromethyl-sulfonyl)imide, tetracyanoborate, trifluroacetate, tri(pentafluroethyl) trifluorophosphate, bis[oxalate(2-)] borate, sulfamate, bis[1,2-benzenediolate (2-)O,O′] borate and perchlorate (ClO₄⁻). Examples of salts with mobile cations include salts containing an alkali metal (such as lithium, sodium, potassium, rubidium, and cesium), a divalent metal (such as magnesium, calcium, strontium, and barium), nitrogen-based salts with small side chains (such as ammonium (NH₄⁺), tetramethylammonium (TMA⁺), tetraethylammonium (TEA⁺), tetrabutyl ammonium (TBA⁺), tetrapentylammonium (TPA⁺), tetrahexylammonium (THA⁺) tetraheptylammonium (THPA⁺)), aromatic nitrogen-based cations (derived from imidazole, pyridine, pyrrole, pyrazole, etc.), morpholinium, piperdinium, phosphonium (such as trihexyl(tetradecyl)phosphonium (THP⁺), sulfonium, and guanidinium. A salt selected for ionic mobility may have both a mobile cation and anion or a mixture of salts could be used to obtain a mixture containing high mobility cations and anions. The inclusion of salts that can rapidly dissociate provides components that can move rapidly at initial ambient temperatures at turn on and at steady operating temperatures of devices (for example from −20 to 85° C.). Ionic salts that are liquid in these temperature ranges are sometimes generally termed “ionic liquids” which are more generally defined as salts whose melting point is relatively low (below 100° C.).

Group II salts for Ionic Stability—Salts that result in the greatest ionic mobility and lowest initial operating voltages may not be the most electrochemically stable. To improve device lifetime, the anion or cation may be chosen for greater electrochemical stability. Examples of salts with greater stability are trifluoromethanesulfonate (CF₃SO₃), also known as triflate (TF⁻), bis(trifluoromethylsulphonyl)imide (TFSI⁻), and related anions containing triflate. The triflate anion is an extremely stable polyatomic ion, being the conjugate base of one of the strongest known acids, triflic acid. Examples of cations with greater electrochemical stability include cyclic cations such pyrrolidinium and piperdinium, and aliphatic and nitrogen-containing cations, such as tetramethylammonium (TMA⁺), tetraethylammonium (TEA⁺), tetrabutylammonium (TBA⁺), tetrapentylammonium (TPA⁺), tetrahexylammonium (THA⁺), and tetraheptylammonium (THPA⁺). A salt selected for stability can contain a more electrochemically stable cation and anion or a mixture of salts can be used to obtain new combinations of more stable cations and anions.

Group III salts for Polymer Compatibility—The aliphatic nature of many salts (for example, those including tetrahexylammonium hexafluorophosphate ions) can lead to issues with phase separation when added to a light emitting polymer containing an aromatic backbone. Improved compatibility can be achieved by adding salts containing aromatic anions or cations. Examples of aromatic cations are tribenzyl-n-octylammonium (BzOA⁺) and benzyltri(n-hexyl) ammonium. Examples of aromatic anions are tetraphenylborate (BP₄⁻ and bis[1,2-benzeneddiobate (2-)-O,O′] borate. A salt selected for compatibility can contain an aromatic cation and anion or a mixture of salts could be used to obtain an aromatic cation and an aromatic anion.

In preferred light emitting layers of the invention which comprise a salt or a mixture of salts (e.g. LECs), a mixture of salts is preferred. Preferably the mixture optimises device performance. Preferably the mixture of salts comprises salts of Group I chosen for ionic mobility at low temperatures, salts of Group II chosen for greater electrochemical stability, and/or salts of Group III chosen for compatibility with aromatic polymers. Preferably the mixture comprises one or more salts from any two of the groups discussed above, and preferably salts from all three groups. Particularly preferably the salts present are THAPF₆ and THPBF₄ or a mixture thereof.

Suitable salts are commercially available, for example, from Sigma Aldrich and Strem Chemicals Inc. The light emitting layer may comprise a salt, or mixture of salts, in an amount of 0 to 10% wt and more preferably 1 to 8% wt based on the dry solid weight of the light emitting layer.

Light emitting layers of the present invention may further comprise a compatabiliser. Preferably light emitting layers of the present invention comprise a compatabiliser when the layered structure is present in an LEC. Preferably the compatabiliser is a copolymer. Still more preferably the compatabiliser is a copolymer of a siloxane, more preferably a C₁₋₆ alkyl siloxane and still more preferably a di C₁₋₆ alkylsiloxane. Still more preferably the compatabiliser is a copolymer of ethylene oxide and/or propylene oxide and more preferably ethylene oxide. Examples of suitable compatibilisers are DBE-821 and Triblock DBP-534. A particularly preferred compatabiliser is a dimethylsiloxane-ethylene oxide block copolymer available from Gelest, Inc under the tradename DBE-821.

The light emitting layer may comprise a compatabiliser in an amount of 0 to 15% wt and more preferably 1 to 8% wt based on the dry solid weight of the light emitting layer.

Light emitting layers of the present invention may further comprise poly(ethylene oxide) (PEO). Preferably light emitting layers of the present invention comprise poly(ethylene oxide) when the layered structure is present in an LEC. In an LEC, still more preferably the light emitting layer comprises a light emitting polymer and poly(ethylene oxide).

The PEO present in the light emitting layer preferably has a volume average molecular weight of 10,000 to 8,000,000. The PEO may be linear, branched or cyclic, but is preferably linear. Preferably the PEO is —OH terminated. Optionally the PEO is substituted.

In the layered structures of the present invention, the light emitting layer preferably has a thickness of 1 nm to 1000 nm. More preferably the light emitting layer has a thickness of 50 nm to 1000 nm. When the layered structures of the present invention are present in an LEC, more preferably the light emitting layer has a thickness of 100 nm to 1000 nm, still more preferably 500 nm to 1000 nm, yet more preferably 800 to 1000 nm, most preferably around 900 nm. When the layered structures of the present invention are present in an OLED, more preferably the light emitting layer has a thickness of 10 nm to 800 nm, more preferably around 10 nm to 500 nm, yet more preferably around 10 nm to 250 nm.

In the structures of the present invention the light emitting layer is deposited by any suitable method. Preferably the light emitting layer is deposited by a solution-based processing method, for example printing. Any conventional solution-based processing method may be used. Representative examples of solution-based processing methods include spin coating, gravure printing, dispense printing, nozzle printing, flexographic printing, roll to roll printing, dip coating, slot die coating, doctor blade coating or ink-jet printing and screen printing. In preferred methods for a light emitting layer for a LEC, the light emitting layer is deposited by dispense printing, screen printing or spin coating. The parameters used for spin coating the light emitting layer such as spin coating speed, acceleration and time are selected on the basis of the target thickness for the layer. Particularly preferably the light emitting layer for a LEC is deposited by printing and in particular dispense printing. In preferred methods for a light emitting layer for an OLED, the light emitting layer is deposited by flexographic printing, gravure printing, ink-jet printing, slot die coating or dispense printing. The parameters used for depositing the light emitting layer are selected on the basis of the target thickness for the layer.

The layered structure of the present invention optionally comprises an organic electron transport layer. When present, the organic electron transport layer is in between the cathode and the light emitting layer. Any conventional electron transport layer may be used. For example, electron injection can be enhanced by using conjugated polyelectrolytes, which comprise pendant groups with ionic functionalities (tetra-alkyl ammonium bromide) attached to a conjugated backbone (C. V. Hoven, A. Garcia, G. C. Bazan, and T.-Q. Nguyen, Adv. Mater. 20, 3793 (2008)). For a non-limiting example of suitable organic electron transport layers, see WO2012/133229. The organic electron transport layer is preferably deposited by a solution-based processing method, for example printing, especially dispense printing. Any conventional solution-based processing method may be used. Representative examples of solution-based processing methods include spin coating, dip coating, dispense printing, gravure printing, nozzle printing, slot die coating, doctor blade coating, ink-jet printing and screen printing. In preferred methods, however, depositing is by dispense printing, screen printing or spin coating, more preferably spin coating. The parameters used for dispense printing, e.g. flow rate, line spacing etc. are selected on the basis of target thickness for the layer. The parameters used for spin coating the light emitting layer such as spin coating speed, acceleration and time are selected on the basis of the target thickness for the layer. An organic electron transport layer is preferably present when the layered structure is to be incorporated into an OLED.

Preferably the organic electron transport layer comprises a polymer. Preferably the optional organic electron transport layer present in the layered structure of the present invention comprises a polymer having a repeat unit of formula (Xa) or (Xb):

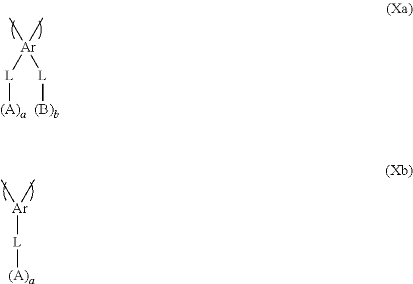

wherein Ar is a C₅₋₂₀ substituted or unsubstituted aryl or heteroaryl group;
L is a bond or a linker group;
A is a polar group; and
B is a polar group, hydrogen, substituted or unsubstituted C₁₋₁₆ alkoxy, substituted or unsubstituted C₅₋₁₄ aryl, substituted or unsubstituted arylalkyl, substituted or unsubstituted C₅₋₁₄ heteroaryl, substituted or unsubstituted heteroarylalkyl and substituted or unsubstituted C₁₋₁₆ alkyl wherein one or more non-adjacent C atoms may be replaced with —O—, —NR—, —NH—, —S—, —COO—, —NHCO—, —NHSO₂—, —NHCOO-groups wherein R is C₁₋₈ alkyl; and
each of a and b are independently an integer selected from 1 to 5

When either of a or b is greater than 1, there are more than 1 A and B groups respectively attached to the linker, e.g. when a is 2, there are 2 A groups attached to the linker. When multiple A and/or B groups are present, they may be attached to the linker at different atoms.

Preferred polymers present in the organic electron transport layer comprise a repeat unit of formula X shown below:

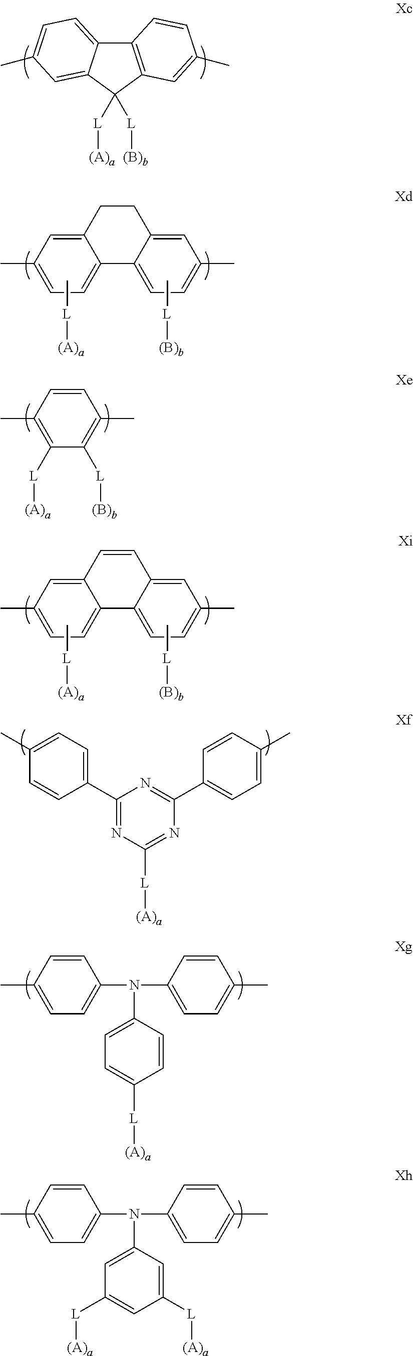

wherein L, A, B, a and b are as defined above in relation to formula Xa and Xb.

Particularly preferably polymer present in the the organic electron transport layer comprises repeat units of formula (Xi):

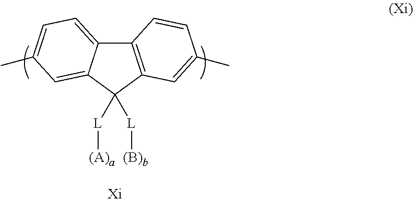

wherein L, A, B, a and b are as defined above in relation to formula Xa and Xb.

In preferred organic electron transport layer polymers, (B)b is (A)a, i.e. the repeat unit comprises identical polar groups per unit. In further preferred organic electron transport layer polymers a is 1 or 2.

In further preferred organic electron transport layer polymers, L is a linker group selected from substituted or unsubstituted C₅₋₁₄ aryl, substituted or unsubstituted C₅₋₁₄ heteroaryl and substituted or unsubstituted C₁₋₁₆ alkyl wherein one or more non-adjacent C atoms may be replaced with —O—, —NR—, —NH—, —S—, —COO—, —NHCO—, —NHSO₂—, —NHCOO-groups wherein R is C₁₋₈ alkyl. More preferably L is a linker group selected from substituted or unsubstituted C₅₋₁₄ aryl and substituted or unsubstituted C₁₋₁₆ alkyl wherein one or more non-adjacent C atoms may be replaced with —O—, —NR—, —NH—, —S—, —COO—, —NHCO—, —NHSO₂—, —NHCOO-groups wherein R is C₁₋₈ alkyl. In some organic electron transport layer polymers, L is a C₅₋₁₄ aryl, especially a C₅ or C₆ aryl, e.g. phenyl. In other organic electron transport layer polymers, L is a C₁₋₁₆ alkyl, more preferably a C₁₋₆ alkyl and yet more preferably a C₁₋₄ alkyl.

Particularly preferably the polymer present in the organic electron transport layer comprises a repeat unit of formula (Xii) or (Xiii):

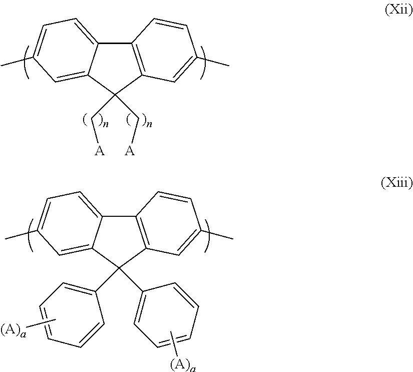

wherein n is an integer between 1 and 16, more preferably an integer between 1 to 6 and yet more preferably an integer between 1 and 4, e.g. 2 and a is 1 or 2. In formula (Xiii) when one A group is present (i.e. a is 1) it is preferably present in the 4 position. In formula (Xiii) when two A groups are present (i.e. a is 2), they are preferably present at the 3 and 4 positions.

In some polymers present in the organic electron transport layer of the present invention A preferably comprises a zwitterionic group. Preferred zwitterionic groups comprise a positively charged N, P, S or O atom, preferably a positively charged N atom. Particularly preferably the zwitterionic group comprises an oxonium, sulfonium, phosphonium or ammonium, still more preferably an ammonium. Further preferred zwitterionic groups comprise a sulfonate, sulfinate, sulfite, thiosulfate, thiosulfonate, phosphate, phosphite, phosphonate, thiophosphate, thiophosphonate, orthophosphate, pyrophosphate, polyphosphate, carboxy, thiocarboxy or alkoxy group. Sulfonate and carbonate are particularly preferred.

Further preferred zwitterionic groups are those of formula (i):

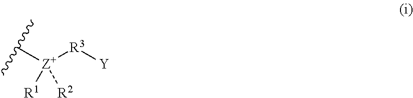

wherein
Z is N, P, O or S;
R¹ is substituted or unsubstituted C₁₋₈ alkyl, substituted or unsubstituted C₂₋₈ alkenyl, substituted or unsubstituted C₅₋₁₄ aryl or substituted or unsubstituted C₅₋₁₄ heteroaryl;
R² is present when Z is N or P and is R¹;
R³ is a C₁₋₁₀ alkylene chain in which non-adjacent carbon atoms may optionally be replaced by —O—, —NR—, —NH—, —S—, —COO—, —NHCO—, —NHSO₂—, —NHCOO-groups wherein
R is C₁₋₈ alkyl; and
Y is SO₃⁻, SO₂⁻, OSO₂⁻, SSO₃⁻, SO₂S⁻, CO₂⁻, PO₃⁻, OPO₃²⁻, OP(OR)O⁻ where R is C1-6 alkyl, OP(S)O₂²⁻, P(S)O₂²⁻, OPO(OH)OPO(OH)O⁻, O—(PO(OH)O)ₙPO(OH)O⁻ wherein n is 1 to 6, CO₂⁻, CSO⁻, or O⁻ group.

In preferred groups of formula (i) Z is N or P, particularly N.

In further preferred groups of formula (i) R¹, and when present R², is an substituted or unsubstituted C₁₋₈ alkyl or substituted or unsubstituted C₅₋₁₄ aryl. More preferably R¹, and when present R², is a C₁₋₆ alkyl, still more preferably a C₁₋₃ alkyl, e.g. methyl.

In further preferred groups of formula (i) R³ is a C₁₋₈ alkyl, more preferably a C₂₋₆ alkyl, e.g. a C₃ or C₄ alkyl.

In further preferred groups of formula (i) Y is SO₃⁻ or CO₂⁻.

In some polymers present in the organic electron transport layer of the present invention A comprises a non-charged polar group. Preferred examples of such polar groups include amide, sulfonamide, ester, carboxylic acid, carbonate, carbamate, ether, alcohol, amine, thioether, sulfide or haloalkyl. Particularly preferred polar groups are those of formula (ii):

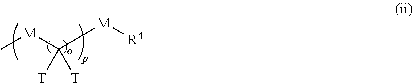

wherein
M is O, NR, NH, S or CQ wherein R is C₁₋₈ alkyl;
Q is Br, Cl, F, I or H, preferably Cl, F or H;
T is Br, Cl, F, I or H;
o is an integer from 1 to 4;
p is an integer from 1 to 16; and
R⁴ is H or C₁₋₆ alkyl.

In preferred groups of formula (ii), M is O, NR or NH, particularly O.

In further preferred groups of formula (ii), T is Cl, F or H, particularly H.

In further preferred groups of formula (ii), o is 2 or 3, particularly 2.

In further preferred groups of formula (ii), p is 1 to 12. In some groups p is more preferably 3 to 10, and still more preferably 4 to 8. In other groups p is more preferably 2 to 6 and still more preferably 2 or 3.

In further preferred groups of formula (ii), R⁴ is H, —CH₃ or —CH₂CH₃.

In some polymers present in the organic electron transport layer of the present invention A comprises an ionic group. Preferred ionic groups comprise a covalently bound anion, particularly a covalently bound anion selected from SO₃⁻, SO₂⁻, OSO₂⁻, SSO₃⁻, SO₂S⁻, CO₂⁻, PO₃⁻, OPO₃²⁻, OP(OR)O⁻ where R is C₁₋₆ alkyl, OP(S)O₂²⁻, P(S)O₂²⁻, OPO(OH)OPO(OH)O⁻, O—(PO(OH)O)ₙPO(OH)O⁻ wherein n is 1 to 6, CO₂⁻, C(S)O⁻, or O⁻. Still more preferably the covalently bound anion is CO₂⁻.

Preferably the ionic group comprises a counter cation selected from Li⁺, Na⁺, K⁺, Rb⁺, Cs⁺, Be²⁺, Mg²⁺, Ca²⁺, Sr²⁺ and Ba²⁺ Still more preferably the cation is Cs⁺.

Particularly preferred polymers present in the organic electron transport layer optionally present in the layered structure of the present invention comprise a repeat unit of formula (Xii) and still more preferably a repeat unit of formula (Xii) wherein a is 1. In such polymers A is preferably a zwitterionic group.

Other particularly preferred polymers present in the organic electron transport layer optionally present in the layered structure of the present invention comprise a repeat unit of formula (Xiii) and still more preferably a repeat unit of formula (Xiii) wherein a is 1. In such polymers A is preferably a non-charged polar group.

Other particularly preferred polymers present in the organic electron transport layer optionally present in the layered structure of the present invention comprise a repeat unit of formula (Xiii) and still more preferably a repeat unit of formula (Xiii) wherein a is 2. In such polymers one A is preferably a non-charged polar group and one A is preferably an ionic group.

Particularly preferred polymers present in the organic electron transport layer optionally present in the layered structure of the present invention comprises a repeat unit of formula (Xiv), (Xv),(Xvi) or (Xvii):

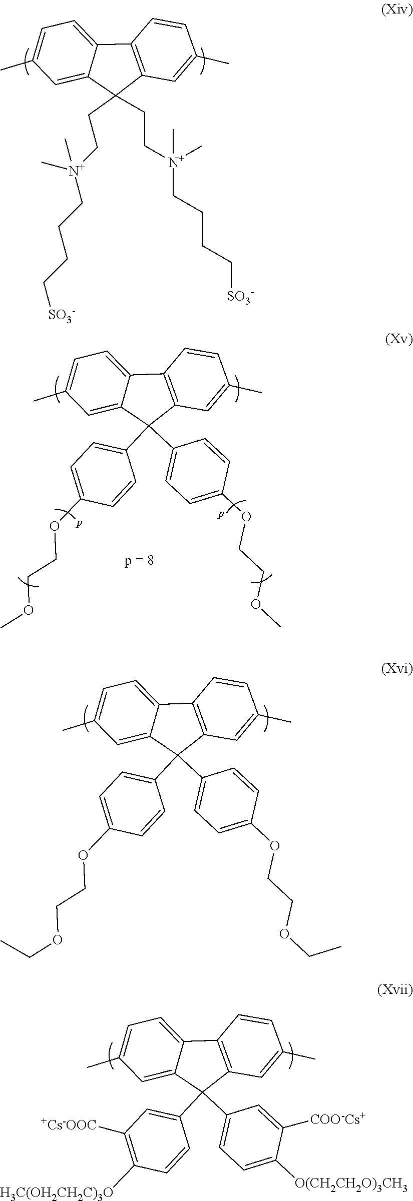

The polymer present in the organic electron transport layer optionally present in the layered structure of the present invention optionally comprises further repeat units. Some preferred polymers comprise a repeat unit of formula (R) which is an substituted or unsubstituted, 2,7-linked fluorene and more preferably a repeat unit of formula (R) as shown below:

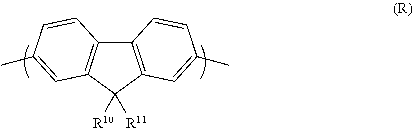

wherein R¹⁰ and R¹¹ are independently selected from hydrogen, substituted or unsubstituted C₁₋₁₆ alkyl, substituted or unsubstituted C₁₋₁₆ alkoxy, substituted or unsubstituted C₆₋₁₄ aryl, substituted or unsubstituted arylalkyl, substituted or unsubstituted C₆₋₁₄heteroaryl and substituted or unsubstituted heteroarylalkyl.

In preferred repeat units of formula (R) R¹⁰ and R¹¹ are the same. In particularly preferred repeat units at least one and more preferably both of R¹⁰ and R¹¹ comprise a substituted or unsubstituted C₁₋₁₆ alkyl or a substituted or unsubstituted C₆₋₁₄ aryl, e.g. a C₆ aryl. Preferred substituents of aryl groups are C₁₋₁₆ alkyl and still more preferably an unsubstituted C₁₋₁₆ alkyl group.

A particularly preferred repeat unit of formula (R) for use in the organic electron transport layer polymer is (Ri) as shown below:

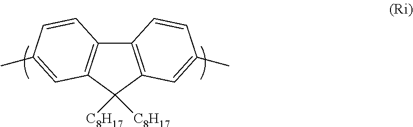

Repeat units of formula (R) may be incorporated into organic electron transport polymers using monomers as described in WO2002/092723.

A particularly preferred organic electron transport layer polymer optionally present in the layered structures of the present invention is (Xvii) as shown below:

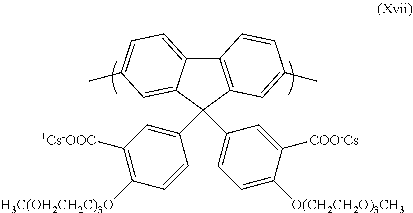

This material and its synthesis are described in US2012/181529, WO2012/3214 and WO2012/133219.

A further aspect of the present invention is an organic electronic device comprising the layered structure as hereinbefore described. Examples of organic electronic devices that comprise the layered structure of the present invention include organic light emitting diodes (OLEDs), light emitting electrochemical cells (LECs), organic photovoltaic devices (OPVs), organic photosensors, organic transistors and organic memory array devices. Preferred devices are OLEDs and LECs. OLEDs and LECs comprise an anode, a light emitting layer and a cathode. More preferably, the device is an LEC.

When the device of the invention is an LEC, in one embodiment, preferably the organic electronic device comprises and preferably consists of:

(i) a cathode;

(ii) at least one light emitting layer; and

(iii) an anode,

wherein the cathode comprises non-transparent carbon or a metal and at least some of the carbon of the cathode is in contact with the light emitting layer.

In another embodiment, the device of the invention is preferably an LEC, and preferably the organic electronic device comprises and preferably consists of:

(i) a non-transparent cathode;

(ii) at least one light emitting layer; and

(iii) an anode.

In case the non-transparent cathode layer comprises a carbon material or a metal, at least some of the carbon material or metal of the cathode is in contact with the light emitting layer.

Preferably the anode comprises ITO or IZO. More preferably the anode comprises ITO. In other preferred devices the anode does not comprise ITO or IZO. Preferably the anode is transparent. Preferably the ITO or IZO present in the anode is deposited by solution processing e.g. printing, preferably screen printing, or by thermal evaporation. The anode is preferably 20 to 200 nm thick and more preferably 10 to 100 nm thick.

Preferred LEC devices of the present invention have one or more of the following structural characteristics:

Substrate: PEN plastic

Anode: ITO

Anode thickness: 20 to 200 nm

Light emitting layer: LEP1-4 as described above, poly(ethylene oxide), dimethylsiloxane-ethylene oxide block tetrahexylammonium hexafluorophosphide (THAPF₆) or trihexyl(tetradecyl)phosphonium tetrafluoroborate (THPBF₄)

Light emitting layer thickness: 50 to 1000 nm, preferably 500 to 1000 nm

Cathode: carbon as hereinbefore defined

Cathode thickness: 100 nm to 30 μm

The LEC device may also include one or more additional layers, e.g. a one or more intermediate layers. In this case the light emitting layer may be deposited on the intermediate layer. Preferably, however, the LEC device does not comprise any such layers.

In preferred embodiments of the invention, the LEC device has a thickness of 200 nm to 30 μm.

When the device of the invention is an OLED, in one embodiment, preferably the organic electronic device comprises:

(i) an anode;

(ii) a hole injection layer;

(iii) an optional hole transport layer

(iv) at least one light emitting layer;

(v) an optional organic electron transport layer; and

(vi) a cathode,

wherein the cathode comprises non-transparent carbon or a metal and at least some of the carbon of the cathode is in contact with the light emitting layer or, when present, the organic electron transport layer.

In another embodiment, when the device of the invention is an OLED, preferably the organic electronic device comprises:

(i) an anode;

(ii) a hole injection layer;

(iii) an optional hole transport layer

(iv) at least one light emitting layer;

(v) an optional organic electron transport layer;

(vi) a non-transparent cathode layer,

(vii) an optional adhesive layer,

(viii) an optional non-reflective layer, and

(ix) a getter layer.

Preferably, when the non-transparent cathode layer comprises a carbon material or a metal, at least some of the carbon material or metal of the non-transparent cathode layer is in contact with the light emitting layer or, when present, the organic electron transport layer.

Preferably the anode comprises ITO or IZO. More preferably the anode comprises ITO. In other preferred devices the anode does not comprise ITO or IZO. Preferably the anode is transparent. Preferably the ITO or IZO present in the anode is deposited by solution processing e.g. printing, preferably screen printing, or by thermal evaporation. The anode is preferably 20 to 200 nm thick and more preferably 10 to 100 nm thick.

The OLED device may also include one or more additional layers, e.g. a hole injection layer, hole transport layer, electron transport layer and/or one or more intermediate layers. In this case the light emitting layer may be deposited on the hole injection layer or hole transport layer. Conventional additional layers which are known in the art for use in OLED devices may be used. For example, electron injection can be enhanced by using conjugated polyelectrolytes, which comprise pendant groups with ionic functionalities (tetra-alkyl ammonium bromide) attached to a conjugated backbone (C. V. Hoven, A. Garcia, G. C. Bazan, and T.-Q. Nguyen, Adv. Mater. 20, 3793 (2008)). For a non-limiting example of suitable organic electron transport layers, see WO2012/133229.

Preferred OLED devices of the present invention have one or more of the following structural characteristics:

Substrate: Glass surface

Anode: ITO

Anode thickness: 20 to 200 nm

Hole injection layer: PEDOT:PSS

Hole injection layer thickness: 100 to 300 nm

Light emitting layer: Polyfluorene, phenanthrene or propellane host polymers or co-polymers with phosphorescent iridium compounds as emitters, or LEP1-3 as described above

Light emitting layer thickness: 10 to 1000 nm, preferably 10 to 500 nm

Electron transport layer: Polymer of formula (Xvii) as described above

Electron transport or injection layer thickness: 10 nm to 125 nm

Cathode: carbon as hereinbefore defined

Cathode thickness: 100 nm to 30 pm

In preferred embodiments of the invention, the OLED has a thickness of 200 nm to 30 μm.

A further aspect of the invention is a method of making a layered structure as hereinbefore defined, comprising:
(i) providing a light emitting layer on a substrate
(ii) optionally depositing an organic electron transport layer on said light emitting layer; and
(iii) depositing a cathode comprising non-transparent carbon on said light emitting layer or, when present, said organic electron transport layer, so that at least some of said carbon is in contact with said light emitting layer or, when present, said organic electron transport layer.

Another aspect of the invention is a method of making a layered structure as hereinbefore defined, comprising the steps of:
providing a light emitting layer on a substrate;
optionally depositing an organic electron transport layer on said light emitting layer;
depositing a non-transparent cathode on said light emitting layer or, when present, said organic electron transport layer;
optionally depositing an adhesive layer which comprises pigments on said cathode layer;
optionally depositing a non-reflective layer on said cathode layer or, if present, said optional adhesive layer; and
depositing a getter layer on said cathode layer or, if present, either said optional adhesive layer or said optional non-reflective layer.

In a more preferred embodiment, the steps of depositing a getter layer, and, if present, a non-reflective layer, on the cathode layer include the deposition of the getter layer (and optional non-reflective layer) on a second and separate substrate, followed by combining the two obtained separate structures, for example by lamination. In this case, preferably, an adhesive layer is used in between the getter layer (or optional non-reflective layer) and the cathode layer to improve lamination. Especially in case all layers are printed, this embodiment using separate substrates facilitates the manufacture of the layered structure.

In the methods of the present invention the light emitting layer is deposited on a surface by a solution-based processing method, for example printing, especially dispense printing. Any conventional solution-based processing method may be used. Representative examples of solution-based processing methods include spin coating, dip coating, dispense printing, gravure printing, nozzle printing, slot die coating, doctor blade coating, ink-jet printing and screen printing. In preferred methods, however, depositing is by dispense printing, screen printing or spin coating. The parameters used for dispense printing, e.g. flow rate, line spacing etc. are selected on the basis of target thickness for the layer. The parameters used for spin coating the light emitting layer such as spin coating speed, acceleration and time are selected on the basis of the target thickness for the layer. Preferably the light emitting layer is deposited by printing and in particular dispense printing or screen printing.

In the methods of the present invention, the organic electron transport layer is preferably deposited by a solution-based processing method, for example printing, especially dispense printing. Any conventional solution-based processing method may be used. Representative examples of solution-based processing methods include spin coating, dip coating, dispense printing, gravure printing, nozzle printing, slot die coating, doctor blade coating, ink-jet printing and screen printing. In preferred methods, however, depositing is by dispense printing, screen printing or spin coating, more preferably spin coating. The parameters used for dispense printing, e.g. flow rate, line spacing etc. are selected on the basis of target thickness for the layer. The parameters used for spin coating the light emitting layer such as spin coating speed, acceleration and time are selected on the basis of the target thickness for the layer.

In some preferred methods of the invention, the cathode is deposited by vapour deposition. In other preferred methods of the invention the cathode is deposited by printing, e.g. by screen printing, gravure printing, flexigraphic printing, roll to roll printing or ink-jet printing. More preferably the cathode is deposited by screen printing. Printing, e.g. screen printing, is carried out by conventional techniques in the art. Preferably the ink is applied to an optionally patterned mesh placed on the surface of a light emitting layer or organic electron transport layer and a squeegee or blade is applied to force the ink through the mesh.

In preferred methods of the invention the cathode is deposited directly on the light emitting layer or organic electron transport layer. Preferably there are no intermediate layers between the cathode and the light emitting layer or organic electron transport layer. Preferably the cathode is deposited directly on the light emitting layer.

In preferred methods of the present invention, if the cathode is deposited by screen printing, it is dried and/or cured following deposition on the light emitting layer. Drying and/or curing is preferably carried out by heating with a box oven, an IR oven or a hot plate. During the drying and/or curing process, the solvent is evaporated and a matrix comprising the carbon particles is formed. The heating also causes the conductive carbon particles present to coalesce to form a conductive track. The skilled man is readily able to determine suitable drying and/or curing conditions.

A further aspect of the present invention is a method of making an organic electronic device (e.g. an LEC) comprising:

(i) providing an anode on a substrate;

(ii) depositing a light emitting layer on or over the anode;

(iii) drying the light emitting layer; and

(iv) depositing a cathode on the light emitting layer;

wherein the cathode comprises non-transparent carbon and at least some of the carbon of the cathode is in contact with the light emitting layer.

When the device is an OLED, the method preferably comprises the steps of:

(i) providing an anode on a substrate;

(ii) optionally providing a hole injection layer and/or a hole transport layer on said substrate;

(iii) depositing a light emitting layer on or over said anode and if present said hole injection layer and/or said hole transport layer;

(iv) drying the light emitting layer;

(v) optionally depositing an organic electron transport layer on said light emitting layer; and

(vi) depositing a cathode on the light emitting layer or, when present, the organic electron transport layer;

wherein the cathode comprises non-transparent carbon and at least some of the carbon of the cathode is in contact with the light emitting layer.

Another aspect of the present invention is a method of producing the above organic electronic device comprising:
providing an anode layer on a substrate;
depositing a light emitting layer on said anode;
drying said light emitting layer;
optionally depositing an organic electron transport layer on said light emitting layer;
depositing a non-transparent cathode layer on said light emitting layer or, when present, said organic electron transport layer;
optionally depositing an adhesive layer which comprises pigments on said cathode layer;
optionally depositing a non-reflective layer on said cathode layer or, if present, said optional adhesive layer; and
depositing a getter layer on said cathode layer or, if present, either said optional adhesive layer or said optional non-reflective layer.

In a more preferred embodiment of said method, the steps of depositing a getter layer, and, if present, a non-reflective layer, on the cathode layer include the deposition of the getter layer (and optional non-reflective layer) on a second substrate, followed by combining the two obtained separate structures, for example by lamination. In this case, preferably, an adhesive layer is used in between the getter layer (or optional non-reflective layer) and the cathode layer. Especially in case all layers are printed, this embodiment facilitates the manufacture of the layered structure. Preferably, the non-transparent cathode layer comprises a carbon material or metal, and at least some of the carbon material or the metal of the cathode is in contact with the light emitting layer.

When the device is an OLED, the method preferably comprises the steps of:

(i) providing an anode on a substrate;

(ii) optionally providing a hole injection layer and/or a hole transport layer on said substrate;

(iii) depositing a light emitting layer on or over said anode and if present said hole injection layer and/or said hole transport layer;

(iv) drying the light emitting layer;

(v) optionally depositing an organic electron transport layer on said light emitting layer; and

(vi) depositing a cathode on the light emitting layer or, when present, the organic electron transport layer.

Preferably, the non-transparent cathode layer comprises a carbon material or metal, and at least some of the carbon material or the metal of the cathode is in contact with the light emitting layer.

In further preferred embodiments, the method further comprises the steps of depositing a hole injection layer on the anode and drying the hole injection layer. In further preferred embodiments, the method further comprises the steps of depositing a hole transport layer on the anode and drying the hole transport layer.

In some embodiments (e.g. OLEDs), the method further comprises depositing one or more additional layers, e.g. intermediate layers. Where the method of the invention is for making an LEC, preferably, the method does not comprise depositing additional layers such as a hole injection layer and drying the hole injection layer.

A further aspect of the present invention is a device (e.g. an organic electronic device) which is obtainable by a method as hereinbefore defined. Preferred devices include organic light emitting diodes (OLEDs), light emitting electrochemical cells (LECs), organic photovoltaic devices (OPVs), organic photosensors, organic transistors and organic memory array devices. Preferred devices are OLEDs and LECs.

A further aspect of the present invention is a use of non-transparent carbon in the manufacture of a cathode for an organic electronic device comprising a light emitting layer, wherein the carbon is deposited directly onto a light emitting layer of the device.

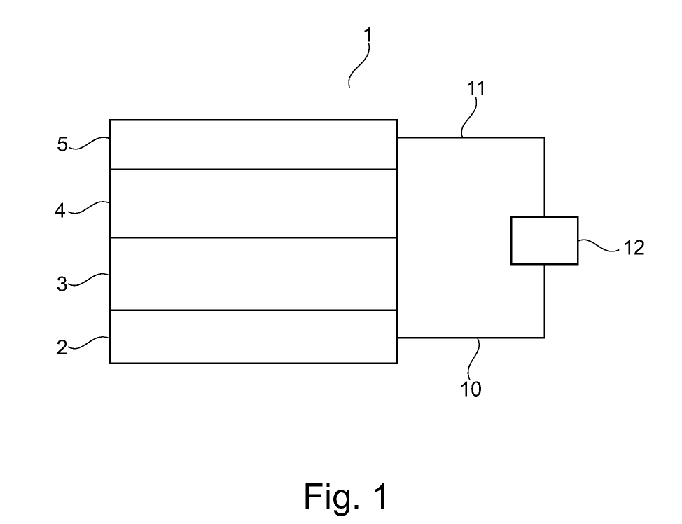

With reference to the Figures, a cross-section through a basic structure of a typical LEC 1 is shown in FIG. 1. A glass or plastic substrate 2 supports an anode 3 comprising, for example, ITO. A light emitting layer 4 is present on the anode layer. Finally a cathode 5 comprises silver or carbon present in a matrix of resin deposited from an ink. Contact wires 10 and 11 to the anode and the cathode respectively provide a connection to a power source 12.

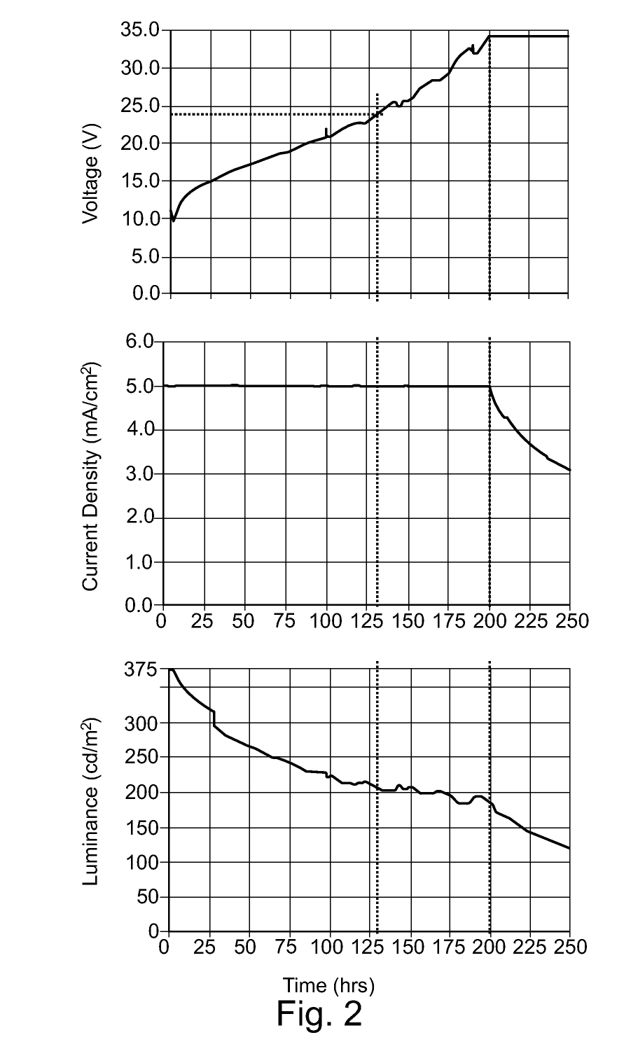

In FIG. 2, an example of lifetest traces is shown for a device having an evaporated Ag cathode, showing the increase in voltage required to achieve a constant current throughout the device over time. The rightmost vertical dashed line indicates the point at which, for this example, the maximum drive voltage of the driver circuitry is reached (34 V, after 200 hours) at which point the driver cannot maintain the constant current, resulting in a reduced current density and consequently a sharp decline in luminance output of the device;

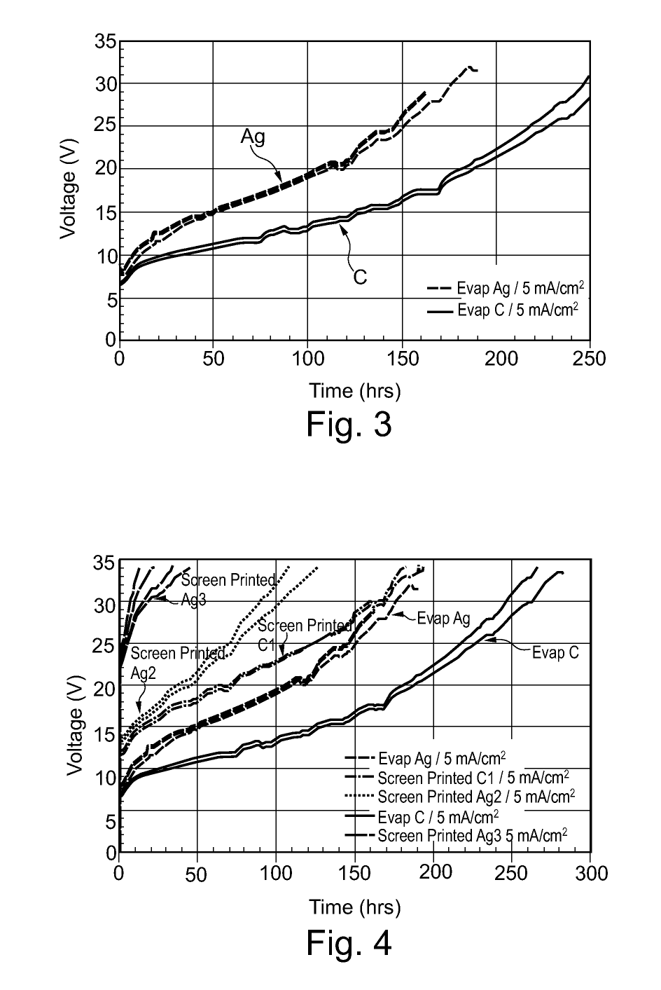

FIG. 3 is a voltage vs. time plot for devices with evaporated cathodes comprising silver and carbon as the cathode material;

FIG. 4 is a voltage vs. time plot for devices with evaporated carbon and silver cathodes and for devices having screen printed silver and carbon cathodes;

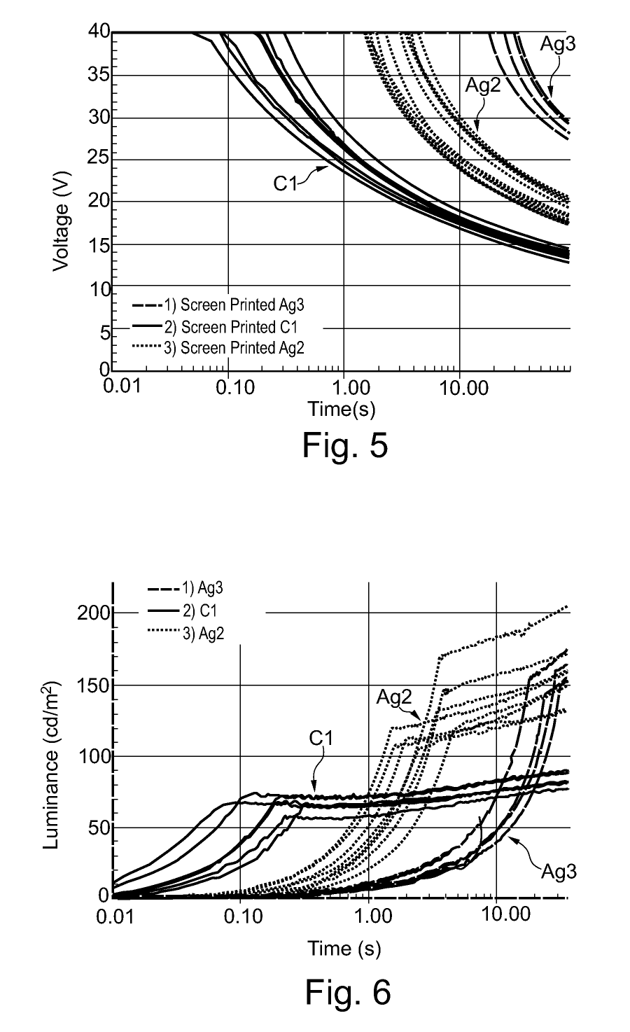

FIG. 5 is a voltage vs. time plot for devices with a screen printed carbon cathode and a screen printed silver cathode.

FIG. 6 is a luminance vs. time plot for devices with a carbon cathode and a silver cathode.

### EXAMPLES

The invention will be illustrated by way of examples, which are intended to illustrate the invention without limiting the invention thereto.

### Materials

The light emitting layer of the LEC comprised a light emitting polymer, poly(ethylene oxide) (PEO), two salts and a compatibiliser.
The solvents used for printing the light emitting layer were 4-methylanisole and chlorobenzene. Both solvents were obtained from Sigma Aldrich.
The light emitting polymer employed was as follows: LEP2 comprises repeat units (Xcg), (Ai), (Di), (Bi) and (Ei) described above. The ratio of the repeat units is 39.95% wt (Xcg), 25% wt (Ai), 5% wt (Di), 30% wt (Bi) and 0.05% wt (Ei).
All light emitting polymers were polymerized by Suzuki polymerization as described in WO0053656.
PEO having a volume average molecular weight of 100K was obtained from Sigma Aldrich.
The compatibiliser was a dialkylsiloxane-ethylene oxide block copolymer, specifically dimethylsiloxane-ethylene oxide block copolymer (DBE-821). DBE-821 was obtained from Gelest, Inc.
The salts were tetrahexylammonium hexafluorophosphide (THAPF₆) and trihexyl(tetradecyl)phosphonium tetrafluoroborate (THPBF₄). There were obtained from Sigma Aldrich or Strem Chemicals Inc.
The LEP layer was deposited to 900 nm dry thickness.
4 different inks were employed as follows: Cl (DuPont 7102), Ag1 (DuPont PV-412), Ag2 (DuPont PV-416), Ag3 (DuPont 5028). The inks are all commercially available from DuPont.
The cathode was carbon or carbon/resin depending on whether it was deposited by vapour deposition or by screen printing, respectively. For comparative examples the cathode was deposited by vapour deposition or by screen printing.
The substrate/anode was ITO on PEN or PET Plastic obtained from, for example, 3M.
Alternative substrates comprising ITO may be obtained from, e.g. Geomatic.

### PREPARATIVE EXAMPLE FOR THE FABRICATION OF A LEC

A device having the structure shown in FIG. 1 was prepared by the method described below.

### (i) Cleaning of ITO Anode

The ITO anode was cleaned in a UV-ozone generator (15 minutes in a USHIO UV ozone generator). The thickness of the anode is 45 nm.

### (ii) Deposition of Light Emitting Polymer

The light emitting polymer was dispense printed using an Assymtek printer from the solvents mentioned above, whereby the solids content of the ink was 2.1% weight to volume. Line speed and line separation were adjusted to achieve the desired film thickness when dried. Following deposition, the light emitting layer was dried at 120° C. on a hotplate for around 2 minutes.

(iii) Deposition of Cathode

The cathodes were blanket-deposited either by thermal evaporation in a vacuum of carbon (to around 30 nm thickness) or silver (to around 100 nm thickness) or by screen printing. Where thermal evaporation was used, the deposition vacuum was around 5×10⁻³ mbar. As an alternative to thermal evaporation, e-beam evaporation or sputtering could also be used. Screen printing was performed on a DEK Horizon 03iX printer using a polyester screen with a 460 threads per inch mesh count. The ink was applied to the screen, distributed during the flood stage and then printed through the mesh using a polyurethane squeegee travelling at a rate of 100 mm/s. The screen height, print pressure and gap were adjusted to ensure good print quality. The thickness of screen printed cathodes was around 10 μm to 30 μm.

### Testing of LEC Device

Current, voltage, and luminance drive characteristics are collected for device performance screening using characterised silicon photodiodes and device spectral output characteristics collected using a calibrated spectrometer system and collection optics. Devices are driven at constant current whilst monitoring IVL both over the initial few minutes of operation and over their operating life span. Refined drive characteristics are collected using calibrated, photometry, colour measurement systems, power supplies and meters.

The environmental conditions under which tests are carried out are stringently controlled, with devices being run in a dry nitrogen atmosphere (less than about 10 ppm O₂ and water, preferably less than about 1 ppm O₂ and water).

### Example 1

A LEC device was prepared as described above, having a vapour deposited carbon cathode. A control device was prepared which had a vapour deposited silver cathode. The voltage required to achieve a constant current density of 5 mA/cm² over time was measured for each device. The results are shown in FIG. 3.

It can be seen from FIG. 3 that the LEC device with a vapour deposited carbon cathode can be operated for a longer period of time before requiring a drive voltage of 24V (a typical drive voltage for many applications) to maintain a constant current density: around 225 hours for the device having a vapour deposited carbon cathode, compared to around 150 hours for the device having a vapour deposited silver cathode.

It can also be seen from FIG. 3 that the device having a vapour deposited carbon cathode displays a slower increase in drive voltage required to maintain a constant current density over time, and requires a lower starting voltage, than the same device having a vapour deposited silver cathode.

### Example 2

A LEC device was prepared as described above, but with a screen printed cathode of carbon (C1) instead of a vapour deposited carbon cathode. Two control devices were also prepared which each had a screen printed cathode of silver (Ag1, Ag3). The screen print inks for C1 and Ag3 contain the same resin and solvent, whereas Ag1 has the same resin but a different solvent. The voltage required to achieve a constant current density of 5 mA/cm² over time was measured for each device. The results are shown in FIG. 4. The results from Example 1 are shown on the same graph for ease of comparison.

It can be seen from FIG. 4 that the screen printed carbon cathode device requires a lower voltage to achieve a constant current density of 5 mA/cm² over time compared to each of the screen printed silver cathode devices. The screen printed carbon cathode device also requires a lower starting drive voltage than each of the control screen printed silver devices. These are the same trends as are observed when comparing the vapour deposited carbon cathode device to the vapour deposited silver cathode device.

The results show that the improved performance of LEC devices having a carbon cathode over comparable devices having a silver cathode is not confined to devices having a vapour deposited cathode. The same improvement in performance is observed in screen printed carbon cathode devices despite the presence of additional resins in such devices. Thus the results show it is the nature of the conductor (i.e. carbon or silver) which governs the different starting voltage and voltage rise on operation, independently of the method by which the conductor is deposited.

### Example 3

The drive voltage for the initial turn-on of newly made devices, described above in Example 2 having screen printed silver and carbon electrodes, and over the first few minutes of operation is shown in FIG. 5.

The results show that the device having a carbon electrode reaches the set current in less time than each of the devices having a silver electrode, as it requires less time to drop below the initial limiting voltage value (40 V in this Example). As a result, the carbon cathode device is quicker to turn on than the silver cathode devices.

### Example 4

The luminance over time of the devices described above in Example 2 is shown in FIG. 6.

The results show that, as a result of the quicker turn on time of the carbon cathode device described above in Example 3, the carbon cathode device reaches a constant luminance at least ten times faster than the silver cathode devices (in the order of 0.1 seconds for the carbon cathode device compared to in the order of 1-5 seconds for the Ag2 silver cathode device and over 10 seconds for the Ag3 silver cathode device). The overall luminance of the carbon cathode device is lower because of the lower reflectivity compared to the silver cathode.

### Example 5

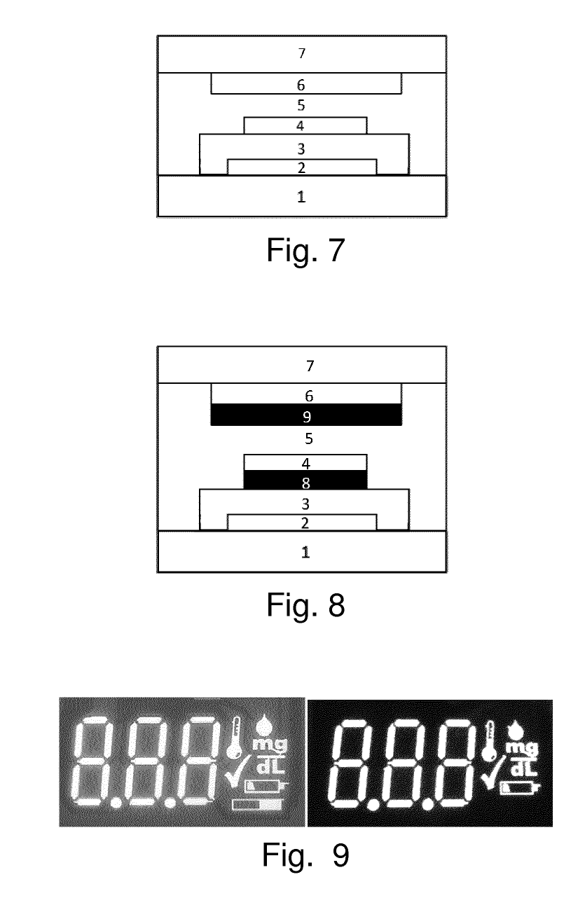

For comparison of the contrast enhancement, a typical LEC device stack was used, said stack having a very simple layer structure, as shown in FIG. 7. In FIG. 7, layers 1 and 7 are plastic barrier substrates, layer 2 represents an ITO anode, layer 3 is a doped organic layer, layer 4 illustrates a cathode, layer 5 represents an adhesive layer, and layer 6 is a getter layer.

The doped organic layer (LEP) 3 is sandwiched between a transparent ITO anode 2 and an Ag cathode 4 deposited by vacuum vapour deposition techniques. For use outside of a glovebox environment the device was encapsulated with a getter layer 6 and barrier substrates 1 and 7 to prevent moisture ingress.

In FIG. 8, a LEC device stack in accordance with the present invention is illustrated, which was used for the comparison to the stack of FIG. 7. In FIG. 8, layers 1 and 7 are plastic barrier substrates, layer 2 is an ITO anode, layer 3 is a doped organic layer, layer 8 is a cathode with layer 4 forming an Ag part of the cathode, layer 5 represents an adhesive layer, layer 6 is a getter layer and layer 9 is a contrast layer.

A getter layer 6 comprising [. . . ] and an added contrast layer 9 were employed. The contrast layer 9 was composed of the same material as the cathode so as to match the colour of the cathode, while the adhesive layer 5 comprised a transparent insulator thus allowing colour matching and preventing short circuits between pixels through the contrast layer.

As shown in the right hand side of FIG. 9, the device in accordance with the present invention has a much more appealing visual appearance and better information clarity.

1. An organic light emitting device having a layered structure comprising:
a getter layer;
an adhesive layer;
a non-transparent cathode layer, comprising a carbon material or a metal;
a light-emitting layer; and
a transparent anode layer;
wherein the getter layer or adhesive layer include light absorbing materials to improve contrast in use, and the getter layer comprises a carbon material or a metal which is substantially identical to the carbon material or metal of the of the cathode layer.

2. (canceled)

3. The device as claimed in claim 1, wherein said non-transparent cathode layer comprises a carbon material selected from the group consisting of isotropic graphite, anisotropic graphite, agranular carbon, non-graphitizable carbon, amorphous carbon, carbon black, carbon fibre, and mixtures thereof.

4. The device as claimed in claim 1, wherein the metal is selected from the group consisting of Ag, Al, Au, Cd, Cr, Cu, Ga, In, Li, Ni, Pb, Pt, Pt black, Sn, Ti and Zn.

5. The device as claimed in claim 1, including a non-reflective layer between the getter layer and the cathode layer.

6. The device as claimed in claim 5, wherein the non-reflective layer comprises a carbon material or a metal.

7. (canceled)

8. The device as claimed in claim 1, wherein in which the adhesive layer includes light absorbing material comprising one or more pigments.

9. The device as claimed in claim 1, wherein said light emitting layer comprises a light emitting polymer.

10. An organic light emitting device as defined in claim 1, wherein said device is a light emitting electrochemical cell.

11. A method of producing the organic light emitting device of claim 1, comprising:
providing an anode layer on a substrate;
depositing a light emitting layer on said anode;
drying said light emitting layer;
depositing a non-transparent cathode layer over said light emitting layer;
depositing a getter layer over said cathode layer.

12. The method according to claim 11, further comprising depositing an organic electron transport layer on said light emitting layer.

13. The method according to claim 11, further comprising depositing an adhesive layer which comprises pigments on said cathode layer.

14. The method according to claim 11, further comprising depositing a non-reflective layer on said cathode layer.

15. The method according to claim 13, further comprising depositing a non-reflective layer on said adhesive layer.

16. An organic light emitting device having a layered structure comprising:
a getter layer;
an adhesive layer;
a non-transparent cathode layer;
a light-emitting layer;
a transparent anode layer; and
a non-reflective layer between the getter layer and the cathode layer;
wherein the getter layer or adhesive layer include light absorbing materials to improve contrast in use, and wherein the non-reflective layer comprises a carbon material or a metal.

17. A device as claimed in claim 16, wherein the non-transparent cathode layer comprises a carbon material or a metal.

18. A device as claimed in claim 17, wherein said non-transparent cathode layer comprises a carbon material selected from the group consisting of isotropic graphite, anisotropic graphite, agranular carbon, non-graphitizable carbon, amorphous carbon, carbon black, carbon fibre, and mixtures thereof.

19. A device as claimed in claim 17, wherein the metal is selected from the group consisting of Ag, Al, Au, Cd, Cr, Cu, Ga, In, Li, Ni, Pb, Pt, Pt black, Sn, Ti and Zn.

20. A device as claimed in claim 16 in which the adhesive layer includes light absorbing material comprising one or more pigments.

21. A device as claimed in claim 16, wherein said light emitting layer comprises a light emitting polymer.

22. An organic light emitting device as defined in claim 16, wherein said device is a light emitting electrochemical cell.
